(19) United States
(12) Patent Application Publication
(10) Pub. No.: US 2017/0125623 A1
(43) Pub. Date: May 4, 2017

(54) DEVICE FOR HARVESTING DIRECT LIGHT AND DIFFUSE LIGHT FROM A LIGHT SOURCE

(71) Applicant: MORGAN SOLAR INC., Toronto (CA)

(72) Inventors: John Paul MORGAN, Toronto (CA); Stefan MYRSKOG, Maple (CA); Brett BARNES, Toronto (CA); Michael SINCLAIR, Toronto (CA); Nigel MORRIS, Toronto (CA)

(21) Appl. No.: 15/401,649

(22) Filed: Jan. 9, 2017

Related U.S. Application Data
(63) Continuation of application No. PCT/IB2015/055178, filed on Jul. 8, 2015.
(60) Provisional application No. 62/022,078, filed on Jul. 8, 2014.

(51) Int. Cl. H01L 31/054

(52) U.S. Cl. CPC H01L 31/0543; H01L 31/0547

(57) ABSTRACT

Device for harvesting light from a light source, comprising: First photovoltaic cell having an upper surface, a lower surface, and an array of optical passages therein. Array of optical concentrating elements above the upper surface defining a light acceptance area, each being associated with one of the optical passages, and being structured/arranged to concentrate direct light towards theretowards. Concentrated direct light passing through the first photovoltaic cell via an optical passage and exiting as a non-parallel light beam. Array of optical redirecting elements below the lower surface, each being associated with one of the optical passages; each receiving the light beam from the optical passage with which it is associated and redirecting it optically towards a second photovoltaic cell. Diffuse light passing through the array of optical concentrating elements to upper surface of first photovoltaic cell. Second photovoltaic cell having an active area being smaller than the light acceptance area.

### CROSS-REFERENCE

The present application claims the benefit of and priority to U.S. Provisional Patent Application Ser. No. 62/022,078, filed Jul. 8, 2014, entitled “Device for Harvesting Direct Light and Diffuse Light from a Light Source”; the contents of which are incorporated herein by reference in their entirety for all purposes.

### FIELD

The present technology relates to devices for harvesting direct light and diffuse light from a light source.

### BACKGROUND

For many reasons, there has been a growth in the development of technologies used to harness renewable sources of energy as an alternative to the generation of energy via combustion of hydrocarbons. One such renewable source of energy that has seen some attention is solar energy.

Devices used to harvest solar energy have been known in the art for some time. The most common of such devices are relatively large flat-panel solar panel assemblies. Such solar panels typically comprise a series of flat “single-junction” crystalline silicon photovoltaic cells that are mechanically and electrically connected together to form a large panel assembly. That panel assembly is then mounted on a supporting structure. Light impinging on the panel assembly enters the photovoltaic cells for harvesting thereby. Solar panel assemblies of this type have been used for some time and remain in use today.

Such solar panel assembles are not suitable for use in many instances owing to the fact that the efficiency of the photovoltaic cells thereof in converting sunlight into electrical energy is relatively low. Thus, in some instances, only a small amount of usable electrical energy would be generated, which would not be sufficient to meet the electrical requirements of the particular intended application. In other instances, a large number of such solar panel assemblies would be required to generate a particular desired amount of electricity, rendering such electricity more expensive to generate than via another method of electrical power generation.

To attempt to overcome this difficulty, high-efficiency photovoltaic cells (“HE-PV cells”) (e.g. triple junction cells) were developed. As their name suggests, such HE-PV cells are materially more efficient at converting sunlight into electrical energy than are the conventional single-junction photovoltaic cells referred to above. The HE-PV cells are also, however, significantly more expensive to manufacture than conventional single-junction photovoltaic cells. So much so that in order to for it to be economically feasible to use such HE-PV cells in a solar electricity generation application where cost is an issue (which is most applications), only an HE-PV cell of a very small size (relative to the conventional single-junction crystalline silicon photovoltaic cells found in the large flat-panel solar panel assemblies referred to above) can be used.

This situation has generated an interest in concentrated photovoltaic (CPV) systems. The theory behind a CPV system is to use optical elements to concentrate sunlight received over a relatively larger area into a relatively smaller area of an HE-PV cell. Since such optical elements are relatively inexpensive, in theory, their combination with an HE-PV cell of a relatively small size would make solar energy generated by such systems economically feasible. (A cost comparison might be made, for example, between the cost of a standard conventional flat-panel solar panel assembly of a given area and a CPV system having a light acceptance area of the same given area.)

There is an important drawback of CPV systems. The optical elements used to concentrate the light impinging on the system have a very small acceptance angle for any incoming light. (Generally, only light within that acceptance angle is accepted by the system for concentration and ultimate harvesting, all other light is generally not harvestable by the system.) This means that in most CPV systems, generally only direct normal light (typically referred to in the art as direct normal irradiance (DNI)) is accepted by the optical elements thereof and is harvestable by the system. Since the sun moves across the sky during the day, it is not economically feasible to stationarily mount a CPV system on a support structure. Typically, such a system is mounted with a two-axis “tracker”, which is a mechanism that reorients the system throughout the day to maintain the entrance of light to the optical elements normal to the sun into order to maximize the amount of DNI that the system receives.

However, not all of the total light received from the sun at a particular location on the Earth by a panel on a tracker (known in the art as global normal irradiance (GNI)) is DNI. Molecules and suspensoids in the Earth's atmosphere will scatter some of the beam of light incoming from the sun to produce what is known in the art as “diffuse light” (i.e. non-direct light in that particular situation). The ratio of DNI to GNI (i.e. how much of the sunlight at a particular location is direct normal sunlight that has not been scattered) varies by location on the Earth and with time. For example, the ratio will be affected by then current meteorological conditions at the location on the Earth receiving the sunlight. On an overcast day in Toronto for example, the ratio is zero as all of the light is diffuse sunlight. On a clear sunny winter day in Toronto, approximately 85% of the sunlight received is DNI (owing to the relative lack of moisture and smog in the air); whereas on a clear sunny summer day in Toronto, approximately 70% of the sunlight received is DNI (owing to the greater presence of moisture and smog in the air).

As was discussed above because of their optical elements' small acceptance angles, conventional CPV systems are generally incapable of harvesting diffuse light. Diffuse light is simply lost to a conventional CPV system, which offsets in part the efficiency gains with respect to the harvesting of direct sunlight in such systems. This also means that even with a tracker there is a portion of the GNI that is inaccessible by the system. For any particular location on the Earth an average annual DNI and DNI to GNI ratio can be calculated in order to evaluate the economics of the installation of a conventional CPV system.

In order to potentially improve the economics of a conventional CPV system, systems have been proposed in which some diffuse light may also be accepted and harvested by the system. In this respect, various “hybrid” systems, being combination of a non-concentrated photovoltaic system with concentrated photovoltaic system have been proposed.

One such hybrid system is described in U.S. Patent Application Publication No. US 2010/0126556 A1, published May 27, 2010, entitled “Photovoltaic Concentrator with Auxiliary Cells Collecting Diffuse Radiation”; the abstract of which provides: “High-concentration photovoltaic concentrators can utilize much more expensive high-efficiency cells because they need so much less of them, but much of the solar resource is left ungathered thereby. The main cell is at the focal spot of the concentrator. Low-cost secondary solar cells are now added to the concentrator, surrounding the main cell. Diffuse skylight and misdirected normal rays irradiate these secondary cells, adding to output. Also, the power plant can have output on cloudy days, unlike conventional concentrators. As cell costs fall relative to other costs, this system becomes economically superior to both flat plate and concentrator systems.”

Another such hybrid system is described in U.S. Patent Application Publication No. US 2012/0255594 A1, published Oct. 11, 2012, entitled “Solar Power Generator Module”; the abstract of which provides: “A solar power generator module includes a first type of photovoltaic cell and a second type of photovoltaic cell. The second type of photovoltaic cell is different from the first type of photovoltaic cell. The module further includes an optical device adapted to concentrate light onto the first type of photovoltaic cell and to transmit diffused light to the second type of photovoltaic cell.”

While hybrid systems such as those described in the '556 Publication and the '594 Publication may be useful, improvements in such hybrid systems are nonetheless possible.

### SUMMARY

It is an object of the present technology to provide an improved device for harvesting both direct and diffuse light as compared with at least some of the prior art.

It is another object of the present technology to provide a hybrid device for harvesting sunlight that combines a concentrating photovoltaic system for harvesting direct sunlight and a non-concentrating photovoltaic system for harvesting diffuse sunlight.

In one of its simplest forms the present technology provides a solar panel device having a concentrating aspect and non-concentrating aspect. (It should be understood that the description of this extremely simple embodiment which follows is not intended to be a definition of the present technology, but simply an aid to understanding the present technology. Embodiments which are far more complex are within the scope of the present technology, and are described in the paragraphs that follow the present paragraph.) In this simple embodiment, the non-concentrating aspect uses a solar panel similar to a conventional non-concentrating solar panel but having a series of holes in some of the panel's non-transparent components. The concentrating aspect uses this solar panel as a support for a series of lenses located on top of the panel and a series of reflectors located on the bottom of the panel. Direct sunlight is focused by the lenses through the holes to the reflectors, which then reflect the light to a high efficiency solar cell for harvesting. Thus, the direct sunlight is harvested by the device as if the device were a concentrated photovoltaic solar device alone. Diffuse sunlight travels through the concentrating elements to the solar panel for harvesting. Thus, the diffuse light is harvested by the device as if the device were a conventional solar panel alone.

Turning now to consider other embodiments, in more general terms, embodiments of the present technology provide a device for harvesting direct light and diffuse light from a light source, the device comprising: (I) A first photovoltaic cell. The first photovoltaic cell has an upper surface, a lower surface, and an array of optical passages therein in optical communication with the upper surface and the lower surface. (II) An array of optical concentrating elements is above the upper surface of the first photovoltaic cell and defines a light acceptance area. Each of the optical concentrating elements is associated with one of the optical passages. Each of the optical concentrating elements is structured and arranged to concentrate direct light from the light source impinging on that optical concentrating element towards the one of the optical passages associated with that optical concentrating element. The concentrated direct light passes through the first photovoltaic cell via the optical passage and exits the first photovoltaic cell via the lower surface as a non-parallel beam of light. Diffuse light from the light source passes through the array of optical concentrating elements to the upper surface of the first photovoltaic cell and enters the first photovoltaic cell for harvesting thereby. (III) An array of optical redirecting elements is below the lower surface of the first photovoltaic cell. Each of the redirecting elements is associated with one of the optical passages. Each of the redirecting elements receives the beam of light from the optical passage with which that redirecting element is associated and redirects the beam of light optically towards a second photovoltaic cell for harvesting thereby. The second photovoltaic cell has an active area receiving the beams of the light. The active area of the second photovoltaic cell is smaller than the light acceptance area defined by the array of optical concentrating elements by a concentration factor.

The first photovoltaic cell has an upper surface, a lower surface, and an array of optical passages therein in optical communication with the upper surface and the lower surface. In the context of the present disclosure, the expression “optical passages” should be understood as including any structure or combination of structures that allows light to pass through that which the optical passage traverses, e.g. the first photovoltaic cell. No particular structure (other than that necessary to accomplish the aforementioned function) is required. Non-limiting examples of optical passages are openings, holes, light pipes, or transparent materials that are appropriately structured and arranged with respect to the light in question. Thus, in the present disclosure, the expression an “array of optical passages therein in optical communication with the upper surface and the lower surface” should be understood as any series of structures that allow light to pass from the upper surface of the first photovoltaic cell through the first photovoltaic cell and to exit from the lower surface of the first photovoltaic cell. The use of the word “array” in this context should not be understood to require a particular ordering or grouping of the optical passages or some portion of the optical passages. Further, each of the optical passages in the array may be identical to the others, although they need not be.

The type, structure, method of manufacturing, and/or principle of operation of an optical passage may be a function of the type, structure, method of manufacturing and/or principle of operation of the first photovoltaic cell (although it may not be). In a non-limiting example, in the case where the first photovoltaic cell is a single-junction crystalline silicon flat-panel structure, the optical passages therein may be holes that have been laser drilled therein.

An array of optical concentrating elements is above the upper surface of the first photovoltaic cell defining a light acceptance area. In the context of the present disclosure, the expression “optical concentrating element” should be understood as including any structure that concentrates light passing through it. Thus, non-limiting examples of optical concentrating elements include lenses, Fresnel lenses, Winston cones, etc. It is not necessary that an optical concentrating element concentrate all of the light that passes through it. It is sufficient that a majority of light passing through a structure be concentrated in order for the structure to be considered an optical concentrating element.

In some embodiments, optical concentrating elements serve the sole function of concentrating the light impinging upon them. In other embodiments, optical concentrating elements serve an additional function with respect to the light. As a non-limiting example, optical concentrating elements may also change the direction of the light impinging on them (e.g. focus the light). In some embodiments, some of the optical concentrating elements have the sole function of concentrating the light impinging on them, while other optical concentrating elements have an additional function(s) with respect to the light. In some embodiments, the additional function(s) are the same as between optical concentrating elements (that have an additional function(s)), while in other embodiments, the additional function(s) differ between optical concentrating elements (that have an additional function(s)).

The use of the word “array” in this context should not be understood to require a particular ordering or grouping of the optical concentrating elements or some portion of the optical concentrating elements. In some embodiments, the optical concentrating elements of the array of optical concentrating elements are all of the same design. In other embodiments, various optical concentrating elements of the array of optical elements are of different designs. The optical concentrating elements being “above the upper surface of the first photovoltaic cell”, includes both structures where the optical concentrating elements are in direct physical contact with the upper surface of the first photovoltaic cell and those where the optical concentrating elements are not direct in physical contact with the upper surface of the first photovoltaic cell (e.g. structures wherein the optical concentrating elements are spaced apart from the upper surface of the first photovoltaic cell).

The array of optical concentrating elements defines a “light acceptance area” of the device. In this respect, each of the optical concentrating elements has a certain cross-sectional area (in a plane normal to the incoming direct light) through which the incoming light can enter that optical concentrating element. The totality of these areas of each of the optical concentrating elements is the light acceptance area of the array.

Each of the optical concentrating elements is associated with one of the optical passages. Thus, an optical concentrating element may be associated with a single one of the optical passages. In such a case, all of the light from that optical concentrating element that enters an optical passage enters a single optical passage (although it may be some of the light from that one of the optical concentrating elements enters no optical passage at all). Alternatively, an optical concentrating element may be associated with more than one of the optical passages. In such a case, the light from that optical concentrating element that enters an optical passage enters more than one optical passage (although, again, it may be that some of the light from that one of the optical concentrating elements enters no optical passage at all). Thus, in some embodiments, each of the optical concentrating elements is associated with a single optical passage. In other embodiments, each of the optical concentrating elements is associated with multiple optical passages. In still other embodiments, some of the optical concentrating elements are associated within a single optical passage while others of the optical concentrating elements are associated with multiple optical passages.

Each of the optical concentrating elements is structured and arranged to concentrate direct light from the light source impinging on that optical concentrating element towards the one(s) of the optical passages associated with that optical concentrating element. It is not required, however, that all of the direct light from the light source impinging on that optical concentrating element enter an optical passage; some of such direct light may not enter an optical passage at all. Nor is it required that only direct light from the light source enter an optical passage; diffuse light may enter an optical passage as well. No particular structure or arrangement of an optical concentrating element (other than that necessary to accomplish the aforementioned function) is necessary in the context of the present technology. In some embodiments, all of the optical concentrating elements are structured and/or arranged in the same fashion. In other embodiments, the structure and/or arrangement of the various optical concentrating elements of a device differ.

In some embodiments the optical concentrating elements are lenses (that are appropriately sized, shaped, structured, and arranged to carry out their required function). In some such embodiments, the lenses are formed in a first single layer of material (as opposed to being discrete individual physical objects).

In some embodiments, each concentrating element is a circular lens (when viewed from above). In some such embodiments, the circular lenses are arranged in a first pattern (when viewed from above) including a series of concentric circles having a first common center (i.e. the circular lenses are themselves arranged in a series of concentric circles). In some such embodiments, for a given one of the series of concentric circles, each of the lenses of that particular one of the series of concentric circles are of a same surface area (i.e., when viewed from above each of the lenses in that particular circle of lenses has the same surface area as each of the other lenses in that particular circle of lenses). In some such embodiments, the common surface area of each of the lenses in a particular circle of lenses increases for each circle of lenses as one progresses away from the common center of all of the circles of lenses.

In some embodiments, the lenses (be they circular lenses or otherwise, and whatever their surface area or construction might be) are arranged in a hexagonal array (pattern). In other embodiments, the lenses (be they circular or otherwise, and whatever their surface or construction area may be) are arranged in a Cartesian array (pattern). In still other embodiments, the lenses (be they circular lenses or otherwise, and whatever their surface area or construction might be) are arranged in a non-regularly-spaced algorithmically-determined array (i.e. the lenses are not randomly placed).

In some embodiments, the optical passages are openings right through the first photovoltaic cell. In some embodiments, where at least some of the concentrating elements are (or include) lenses, a lens has a focal point located with respect to its respective optical passage such that direct light concentrated by that lens passes through its respective opening in the first photovoltaic cell. Between different embodiments the actual location of the focal point with respect to the opening will vary, for example depending on the focal angle and focal length of the lens, the thickness of the first photovoltaic cell, and the size of the opening, in that particular embodiment. The focal point can be located with respect to the opening at any location in which the passage of light through the opening is not materially impeded. Thus, in some embodiments the focal point is centered between the entrance to and the exit from the opening. In other embodiments, the focal point is within the opening either closer to the entrance or closer to the exit thereof. In still other embodiments, the focal point is not within the opening but is close to either the entrance or the exit thereof.

The concentrated direct light passes through the first photovoltaic cell via the optical passage and exits the first photovoltaic cell via the lower surface. It is not necessary, however, that all of the light entering an optical passage exit the first photovoltaic cell via the lower surface, or indeed exit the photovoltaic cell at all. In some embodiments, some of the light entering an optical passage may be absorbed by the first photovoltaic cell. In some embodiments, some of the light entering an optical passage may exit the first photovoltaic cell other than via the lower surface. (In a non-limiting example, light entering the optical passage may be reflected back and exit the first photovoltaic cell via the upper surface.) It is only necessary that at least some of the light entering an optical passage exit the first photovoltaic cell via the lower surface; although in many embodiments, the device is structured to attempt to maximize the amount of light exiting the first photovoltaic cell via the lower surface. It is not necessary that light be identically treated by each optical passage; the treatment and/or resultant fate of light entering different optical passages may differ.

Light exits via the lower surface of the first photovoltaic cell as a non-parallel beam. This does not require that all of the light rays exiting in a beam be non-parallel, only that the majority of rays exiting at any one time be non-parallel. Thus, in some embodiments, the light rays in an exiting beam will be partially or entirely divergent. In other embodiments, the light rays in an exiting beam will be partially or entirely convergent. In still other embodiments, the light rays in an exiting beam will be a mixture of (at least) convergent and divergent. In some embodiments, the light rays in a beam exiting the lower surface of the first photovoltaic cell are in a similar pattern as with other exiting beams. In other embodiments, the light rays in the beams exiting the lower surface of the first photovoltaic cell will be in a different pattern as between (at least some) different exiting beams.

There is an array of optical redirecting elements below the lower surface of the first photovoltaic cell. In the context of the present disclosure, the expression “optical redirecting element” should be understood as including any structure that changes the direction of light impinging upon it. Thus, non-limiting examples of optical redirecting elements include mirrored surfaces, surfaces that reflect light via total internal reflection, etc. It is not necessary that an optical redirecting element change the direction of all of the light rays that impinge upon it. It is sufficient that a majority of the light rays impinging upon a structure change their direction of travel in order for the structure to be considered an optical redirecting element.

In some embodiments, optical redirecting elements serve the sole function of redirecting the light impinging upon them. In other embodiments, optical redirecting elements serve an additional function with respect to the light. As a non-limiting example, optical redirecting elements may also concentrate the light impinging on them. In some embodiments, some of the optical redirecting elements have the sole function of changing the direction of light impinging on them, while other optical redirecting elements have an additional function(s) with respect to the light. In some embodiments, the additional function(s) are the same as between optical redirecting elements (that have an additional function(s)), while in other embodiments, the additional function(s) differ between optical redirecting elements (that have an additional function(s)).

Again, the use of the word “array” in this context should not be understood to require a particular ordering or grouping of the optical redirecting elements or some portion of the optical redirecting elements. In some embodiments, the optical redirecting elements of the array of optical redirecting elements are all of the same design. In other embodiments, various optical redirecting elements of the array of optical elements are of different designs. The optical redirecting elements being “below the lower surface of the first photovoltaic cell” includes both structures wherein the optical redirecting elements are in direct physical contact with the lower surface of the first photovoltaic cell and those wherein the optical redirecting elements are not direct in physical contact with the lower surface of the first photovoltaic cell.

Each of the optical redirecting elements is associated with one of the optical passages. Thus, an optical redirecting element may be associated with a single one of the optical passages. In such a case, all of the light that that optical redirecting element receives via an optical passage is received from a single optical passage (although it may be that some of the light that that optical redirecting element receives is received other than via an optical passage). Alternatively, an optical redirecting element may be associated with more than one of the optical passages. In such a case, the light that that optical redirecting element receives via an optical passage is received from more than one optical passage (although, again, it may be that some of the light that that optical redirecting element receives is received other than via an optical passage). In some embodiments, each of the optical redirecting elements is associated with a single optical passage. In other embodiments, each of the optical redirecting elements is associated with multiple optical passages. In still other embodiments, some of the optical redirecting elements are associated within a single optical passage while others of the optical redirecting elements are associated with multiple optical passages.

Each of the redirecting elements receives the beam of light from the optical passage with which that redirecting element is associated and redirects the beam of light optically towards a second photovoltaic cell for harvesting thereby. Each of the optical redirecting elements is structured and arranged to accomplish this function, however, no particular structure or arrangement of an optical redirecting element (other than that which accomplishes the aforementioned function) is necessary in the context of the present technology. In some embodiments, all of the optical redirecting elements are structured and/or arranged in the same fashion. In other embodiments, the structure of and/or arrangement of (at least some of) the various redirecting elements of a device differ.

It is not required that all of the light exiting the first photovoltaic cell via the lower surface thereof be redirected by a redirecting element; some of such light may not be redirected. Nor is it required that only light exiting the first photovoltaic cell via the lower the surface be the only light redirected by a redirecting element; a redirecting element may also redirect (or otherwise affect) other light as well.

In some embodiments, the optical redirecting elements are reflectors and redirecting the beam of light occurs via total internal reflection. In some such embodiments, the reflectors each have a shape including a portion of a quadratic surface (e.g. paraboloidal, hyperboloidal, ellipsoidal, etc.). In some such embodiments, the reflectors both change the direction of and concentrate the light beams. In such embodiments, it is not required that each of the reflectors be of the same shape (although they may be). In some embodiments, the reflectors are formed in a second single layer of material (as opposed to being discrete individual physical objects).

In some embodiments, the redirecting elements redirect the beams of light directly towards the second photovoltaic cell. (I.e. there is no further optically active element that materially changes the direction of travel of the light having been redirected by an optical redirecting element towards the second photovoltaic cell prior to the light impinging upon the second photovoltaic cell.) In some such embodiments, the optical redirecting elements are shaped and arranged (one with respect to each other and with respect to other optically active elements of the device) such that at least 75% of each beam of light has an unobstructed path from the optical redirecting element associated therewith to the second photovoltaic cell. In some such embodiments, the optical redirecting elements are shaped and arranged such that each beam of light has an unobstructed path from the optical redirecting element associated therewith to the second photovoltaic cell.

In some embodiments, the optical redirecting elements are arranged in a second pattern (when viewed from below) including a second series of concentric circles having a second common center (i.e. the optical redirecting elements are themselves arranged in a series of concentric circles).

In some embodiments, the optical redirecting elements are arranged in an array (pattern) similar to that of the lenses.

The second photovoltaic cell is distinct from the first photovoltaic cell. The second photovoltaic cell has an active area receiving the beams of the light; i.e., those that have been concentrated by the optical concentrating elements, traversed the first photovoltaic cell via an optical passage, and been redirected by the optical redirecting elements. (In some embodiments, the second photovoltaic cell may also harvest light other than the aforementioned beams of light.) The active area of the second photovoltaic cell is smaller than the light acceptance area defined by the array of optical concentrating elements by a concentration factor. The concentration factor is any rational number greater than 1; the concentrator factor need not be a whole number. The concentration factor can be determined by dividing the light acceptance area defined by the array of optical concentrating elements by the active area of the second photovoltaic cell associated with that array of optical concentrating elements. No particular concentration factor is required in the context of the present technology.

Diffuse light from the light source passes through the array of optical concentrating elements to the upper surface of the first photovoltaic cell and enters the first photovoltaic cell for harvesting thereby. It is not required, however, that all of the diffuse light impinging on the device enter the first photovoltaic cell. As was discussed above, in some embodiments, some of the diffuse light enters an optical passage in the first photovoltaic cell. In some embodiments, some of the diffuse light reflects off the upper surface of the first photovoltaic cell. In some embodiments, some of the diffuse light is prevented from reaching the upper surface of the first photovoltaic cell by some other structure of the device.

In some embodiments, environmental albedo light (e.g. diffuse light from the light source having been reflected off a surface behind the device—usually the ground) enters the lower surface of the first photovoltaic cell for harvesting thereby.

It is not required that diffuse light remain untreated by any optical element prior to its entry into the first photovoltaic cell (although this is indeed the case in some embodiments). In some embodiments, for example, some (or all) diffuse light may be treated by an optical element or system of elements (which can include, for example, the optical concentrating elements described above, or otherwise) prior to its entry into the first photovoltaic cell.

It is not required that all of the diffuse light entering the first photovoltaic cell actually be harvested by the first photovoltaic cell. For example, photovoltaic cells are commonly not 100% efficient at harvesting the light that enters them.

It can thus be seen that via use of the present technology, direct light and diffuse light impinging on the device are generally harvested by different photovoltaic cells, the second photovoltaic cell and the first photovoltaic cell, respectively. In some embodiments, the second photovoltaic cell is a multiple-junction photovoltaic cell, e.g. a high efficiency cell. In some embodiments, the first photovoltaic cell is a single-junction photovoltaic cell. In some embodiments, the second photovoltaic cell is a single photovoltaic cell. In other embodiments, the second photovoltaic cell is multiple photovoltaic cells (which may be in direct physical contact with one another, spaced apart from one another, or some combination thereof.)

In some embodiments, the second photovoltaic cell has an upper surface and a lower surface (which are defined consistently with the upper surface and the lower surface of the first photovoltaic cell). The beams of light (directly or indirectly) from the array of optical redirecting elements enter the second photovoltaic cell through the lower surface thereof (i.e. generally opposite from the direction which the diffuse light generally enters the first photovoltaic cell). In some embodiments, the beams of light enter the second photovoltaic cell only through the lower surface thereof. In some such embodiments, the upper surface of the second photovoltaic cell is adjacent the lower surface of the first photovoltaic cell (i.e. the two are “back to back”).

In other embodiments, the second photovoltaic cell is vertically spaced apart from the first photovoltaic cell, such that there is a gap between them. In some such embodiments, the beams of light (directly or indirectly) from the array of optical redirecting elements enter the second photovoltaic cell through the upper surface thereof. In some such embodiments the beams of light enter the second photovoltaic cell only through the upper surface thereof. In other such embodiments the beams of light enter the second photovoltaic cell through both the upper surface and the lower surface thereof.

In some embodiments, the device further comprises an optical collecting element. In the context of the present disclosure, the expression “optical collecting element” should be understood as any structure that receives light from more than one optical source element (of whatever kind) and redirects at least some of the received light to a common optical destination element (of whatever kind). Thus, non-limiting examples of optical collecting elements include appropriately shaped, structured and arranged mirrored surfaces, surfaces that reflect light via total internal reflection, etc. An optical collecting element is structured and arranged to accomplish the aforementioned function, however, no particular structure or arrangement (other than that which accomplishes the aforementioned function) is necessary in the context of the present technology. It is not required in the context of the present technology that an optical collecting element be a single physical structure. Multiple or compound structures that accomplish the aforementioned function can, in some embodiments, be considered a single optical collecting element.

It is not necessary that an optical collecting element redirect all of the light received by it to a common optical destination element. It is sufficient that at least some light from at least more than one different optical source element is redirected to a common optical destination element in order for the structure to be considered an optical collecting element. It is not necessary that an optical collecting element redirect light received by it to a single common optical destination element. In some embodiments (in a non-limiting example, such as those wherein the second photovoltaic cell is multiple photovoltaic cells) an optical redirecting element redirects light received by it from multiple optical source elements to multiple common optical destination elements.

In some embodiments, an optical collecting element serves the sole function of receiving and redirecting light as described herein above. In other embodiments, an optical collecting element serves an additional function with respect to the light (whatever that function may be).

In some embodiments, a device of the present technology has more than one optical collecting element. In such cases, in some embodiments, all of the optical collecting elements are structured and/or arranged in the same fashion. In other embodiments, the structure and/or arrangement of the various optical collecting elements of a device differ.

The optical collecting element receives the beams of the light from the array of optical redirecting elements and reorients (e.g. changes the direction of) the beams of light optically towards the second photovoltaic cell. In the context of the present disclosure, “optically towards the second photovoltaic cell” should be understood as the optical collecting element redirecting the light downstream to the next optically active element in the light's optical path towards the second photovoltaic cell, irrespective of the relationship of that optical path to the actual physical location of the second photovoltaic cell. It is not required that the optical collecting element reorient all of the light that it receives; it is sufficient that the optical collecting element reorient the majority of the light that it receives.

Thus, in some embodiments, the optical collecting element reorients the beams of light directly towards the second photovoltaic cell (i.e. there is no further optically active element that materially changes the direction of travel of the light having been reoriented by the optical collecting element towards the second photovoltaic cell prior to the light impinging upon the second photovoltaic cell).

In some embodiments, the optical redirecting elements are shaped and arranged (one with respect to each other and with respect to other optically active elements of the device) such that at least 75% of the each beam of light (having been redirected by an optical redirecting element) has an unobstructed path from the optical redirecting element associated with that beam of light to the optical collecting element. In some such embodiments, the optical redirecting elements are shaped and arranged such that each beam of light has an unobstructed path from the optical redirecting element associated therewith to the optical collecting element.

In some embodiments, the optical collecting element has a revolved reflective surface including a portion of a quadratic surface (e.g. paraboloidal, hyperboloidal, ellipsoidal, etc.) in cross-section. In some such embodiments, the optical collecting element both changes the direction of and concentrates the light impinging upon it. In some embodiments, the revolved reflective surface is formed in a third single layer of material (as opposed to being formed of discrete individual physical objects). In some embodiments, an axis of revolution of the revolved reflective surface passes through the first common center (of the lenses when arranged in the first series of centric circles) and the second common center (of the optical redirecting elements when arranged in the second series of centric circles). In some embodiments, the axis of revolution of the revolved reflective surface passes through the second photovoltaic cell.

It should be understood, however, that the present technology does not require the presence of an optical collecting element.

In some embodiments, the second photovoltaic cell is in thermal communication with the first photovoltaic cell, and the first photovoltaic cell is the primary heat sink of the second photovoltaic cell; i.e., the majority of the heat from the second photovoltaic cell transferred away from the second photovoltaic cell by conduction is transferred to the first photovoltaic cell.

In some embodiments, the second photovoltaic cell is in thermal communication and electrical communication with an electric circuit sandwiched within the device. The electric circuit is the primary heat sink of the second photovoltaic cell; i.e. the majority of the heat from the second photovoltaic cell transferred away from the second photovoltaic cell by conduction is transferred to the electrical circuit sandwiched within the device.

In the context of the present specification, the words “first”, “second”, “third”, etc. have been used as adjectives only for the purpose of allowing for distinction between the nouns that they modify from one another, and not for the purpose of describing any particular relationship between those nouns. Thus, for example, it should be understood that, the use of the terms “first” device and “third” device is not intended to imply any particular order, type, chronology, hierarchy or ranking (for example) of/between the devices, nor is their use (by itself) intended imply that any “second” device must necessarily exist in any given situation. Further, as is discussed herein in other contexts, reference to a “first” element and a “second” element does not preclude the two elements from being the same actual real-world element. Thus, for example, in some instances, a “first” device and a “second” device may be the same device, in other cases they may be different devices.

Embodiments of the present technology each have at least one of the above-mentioned object and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of embodiments of the present technology will become apparent from the following description, the accompanying drawings and the appended claims.

### BRIEF DESCRIPTION OF THE DRAWINGS

For a better understanding of the present invention, as well as other aspects and further features thereof, reference is made to the following detailed description of certain embodiments which is to be used in conjunction with the accompanying drawings, where:

FIG. 1 is a perspective view of a solar panel assembly being a first embodiment of the present technology.

FIG. 2 is a perspective view the solar panel assembly of FIG. 1 with the optical concentrating units removed.

FIG. 3 is a close-up perspective view of one of the single-junction photovoltaic assemblies of the solar panel assembly of FIG. 1 along with optical concentrating units and optical redirecting/collecting units.

FIG. 4 is an exploded perspective view of one of the single junction photovoltaic assemblies of the solar panel assembly of FIG. 1 along with optical concentrating units and optical redirecting/collecting units.

FIG. 5 is a cross-section of the solar panel assembly of FIG. 1 taken along the line 5-5 in FIG. 3.

FIG. 5A is a schematic view showing the path of light taken through a portion of the solar panel assembly of FIG. 1.

FIG. 5B is the same as FIG. 5, but without most reference numerals, for clarity.

FIG. 6 is a bottom plan view of the electrical conductor and portions of the electrical insulator of the solar panel assembly of FIG. 1.

FIG. 7 is a close-up view focused on a multiple-junction photovoltaic cell as indicated in FIG. 6.

FIG. 8 is a top plan view of the solar panel assembly of FIG. 1 as illustrated in FIG. 3.

FIG. 9 is a three-dimensional perspective cross-section view of a portion of a solar panel assembly being a second embodiment of the present technology.

FIG. 10 is a close-up three-dimensional perspective cross-section view of the portion of the solar panel assembly of FIG. 9.

FIG. 11 is a schematic view of a portion of the solar panel assembly of FIG. 9.

FIG. 11A shows the path light rays take through the assembly of FIG. 11.

FIG. 12 is a schematic view of a portion of the solar panel assembly of FIG. 9.

FIG. 12A shows the path light rays take through the assembly of FIG. 12.

FIG. 13 is a schematic view of a portion of the solar panel assembly of FIG. 9.

FIG. 13A shows the path light rays take through the assembly of FIG. 13.

FIG. 14 is a schematic view of a portion of the solar panel assembly of FIG. 9.

FIG. 14A shows the path light rays take through the assembly of FIG. 14.

FIG. 15 is a schematic view of a portion of the solar panel assembly of FIG. 9.

FIG. 16 is a cross-sectional schematic view of a portion of a solar panel assembly being a third embodiment of the present technology.

FIG. 17 is a cross-sectional schematic view of a portion of a solar panel assembly being a fourth embodiment of the present technology.

FIG. 18 is a cross-sectional schematic view of a portion of a solar panel assembly being a fifth embodiment of the present technology.

FIG. 19 is a cross-sectional schematic view of a portion of a solar panel assembly being a sixth embodiment of the present technology.

FIG. 20 is a cross-sectional schematic view of a portion of a solar panel assembly being a seventh embodiment of the present technology.

FIG. 21 is a schematic view of a lens array.

FIG. 22 is a schematic view of a lens array.

FIG. 23 is a schematic view of a lens array.

FIG. 24 is a schematic perspective view of a solar panel assembly illustrating a lens array.

FIG. 25 is a plan view of an embodiment of an electrical conductor.

FIG. 25A is a close-up plan view of the electrical conductor of FIG. 25.

FIG. 26 is a plan view of an embodiment of an electrical conductor.

FIG. 26A is a close-up plan view of the electrical conductor of FIG. 26.

In the figures there are a shown various solar panel assemblies including various embodiments of the present of the technology. It is to be expressly understood that the various solar panel assemblies shown in the figures are merely some exemplary embodiments of the present technology. These are not, however, the only embodiments of the present technology. Thus, the description that follows is intended to be only a description of illustrative examples of the present technology. This description is not intended to define the scope or set forth the bounds of the present technology.

In some cases, what are believed to be helpful examples of modifications to certain solar panel assemblies being embodiments of the present technology may also be set forth in the description below. This is done merely as an aid to understanding, and, again, not to define the scope or set forth the bounds of the present technology. Where set forth, these modifications are not intended to be an exhaustive list, and, as a person skilled in the art would understand, other modifications are likely possible. Further, where this has not been done (i.e. where no examples of modifications have been set forth), it should not be interpreted that no modifications are possible and/or that what is described is the sole manner of embodying that element of the present technology. As a person skilled in the art would understand, this is likely not the case.

In addition it is to be understood that the solar panel assemblies described below may provide in certain instances simple or simplified embodiments of the present technology, and that where such is the case they have been presented in this manner as an aid to understanding. As persons skilled in the art would understand, various embodiments of the present technology will be of a greater complexity.

### DETAILED DESCRIPTION OF CERTAIN EMBODIMENTS

### First Embodiment (Overview)

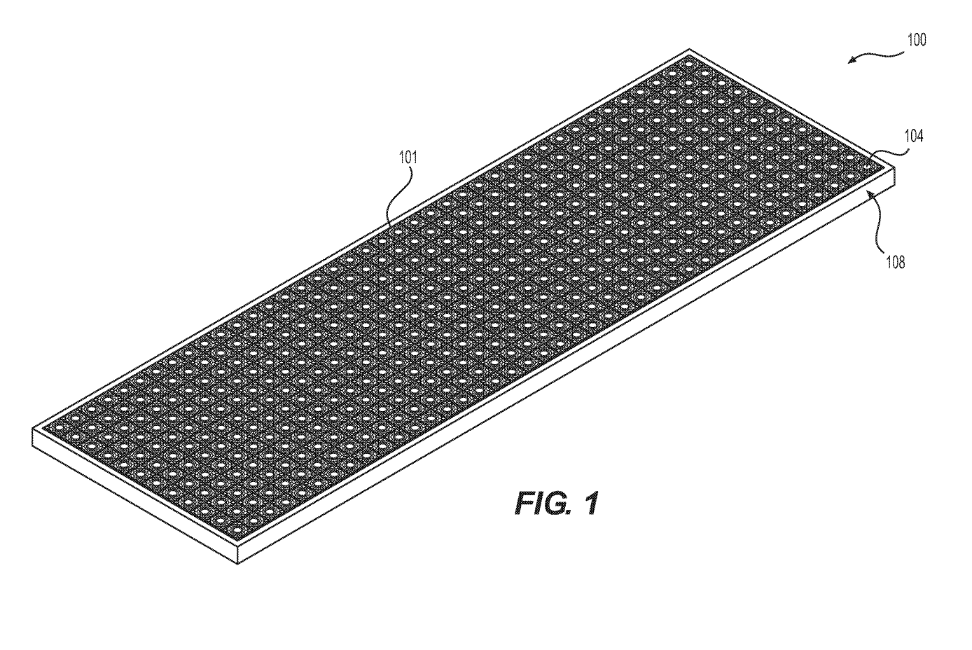

Referring to FIG. 1, there is shown a perspective view solar panel assembly 100 for harvesting both direct and indirect sunlight, being an embodiment of the present technology. The solar panel assembly 100 is a “hybrid” solar panel assembly in that it has a concentrated photovoltaic aspect and a non-concentrated photovoltaic aspect. The solar panel assembly 100 has an upper surface 101 upon which sunlight to be harvested by the solar panel assembly 100 impinges, and enters the solar panel assembly 100. The upper surface 101 has a plurality of optical concentrating units 104. Each of the optical concentrating units 104 has an array of lenses 106 (not labelled in FIG. 1) that are structured and arranged to concentrate direct sunlight impinging on that lens 106. These optical concentrating units 104 are described in further detail below. A frame 108 surrounds the solar panel assembly 100 providing structural integrity and edge protection to the solar panel assembly 100. The dimensions of the solar panel assembly 100 are 1650 mm (length)×500 mm (width)×12 mm (depth). In this embodiment, the dimensions of the solar panel assembly 100 are slightly larger than the total of the dimensions of the all of the optical concentrating units 104 because of small spaces between the units 104 and the presence of the frame. In other embodiments the dimensions of the solar panel assembly 104 differ, with no particular dimensions being required in the context of the present technology.

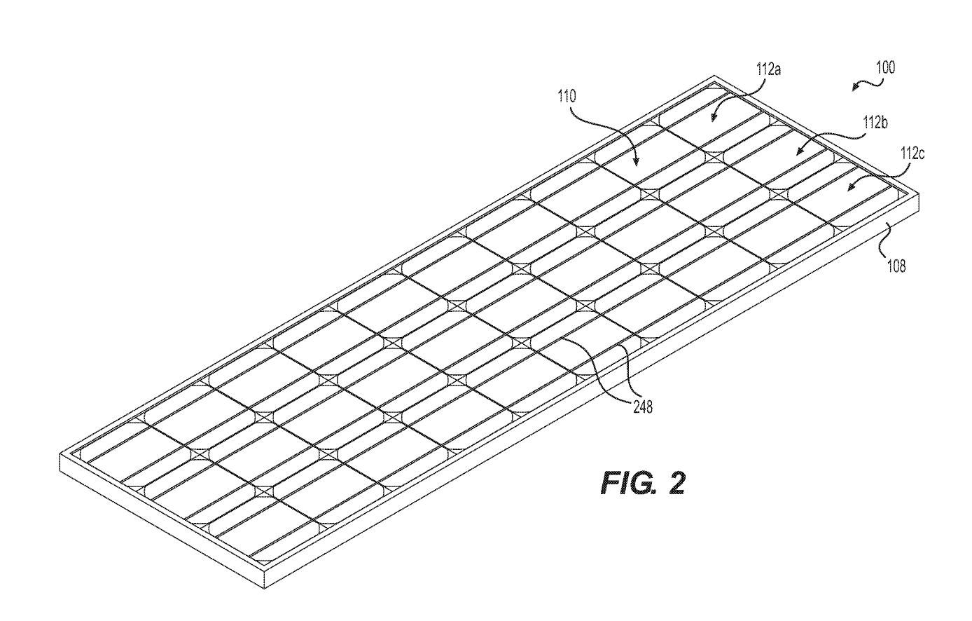

FIG. 2 shows the solar panel assembly 100 of FIG. 1 with the optical concentrating units 104 removed (for illustrative purposes). Below the optical concentrating units 104 is a layer 110 comprised of a plurality of flat-panel single-junction crystalline silicon photovoltaic cell assemblies 112a, 112b, 112c etc. Diffuse sunlight impinging on an optical concentrating unit 104 generally passes through that optical concentrating unit 104 to the single-junction photovoltaic cell assembly 112 below for harvesting.

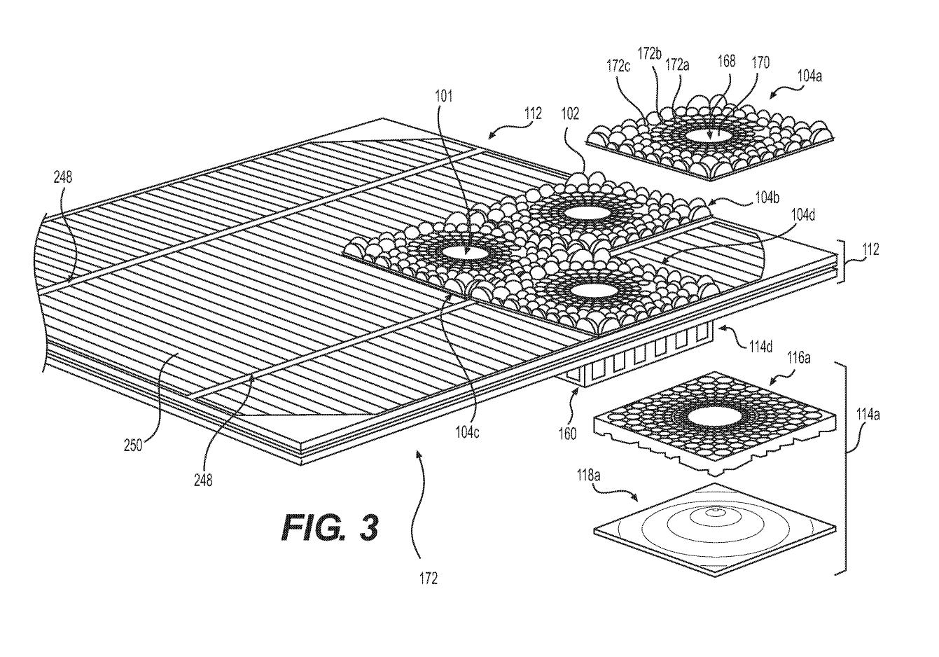

FIG. 3 shows a close-up perspective view of one of the single-junction photovoltaic cell assemblies 112 along with four optical concentrating units 104a, 104b, 104c, 104d and two optical redirecting/collecting unit assemblies 114a, 114d of the solar panel assembly 100. In this embodiment, each of the single-junction photovoltaic cell assemblies 112 has the following dimensions: 150 mm (length)×150 mm (width)×0.2 mm (depth). In this embodiment each of the optical concentrating units 104 has the following dimensions: 37.5 mm (length)×37.5 mm (width)×3 mm (depth). Thus, FIG. 3 shows the relative size relationship between an optical concentrating unit 104 and a single junction photovoltaic cell assembly 112 in this embodiment. In this embodiment, each single-junction photovoltaic cell assembly 112 is associated with sixteen optical concentrating units 104. In other embodiments, the sizes and shapes of the single-junction photovoltaic cell assembly 112 and/or the optical concentrating units 104 (where they are present in that embodiment) will vary, as will the ratio of the latter to the former. No particular such size, shape or ratio is required in the context of the present technology.

As is also shown in FIG. 3, below the bottom surface (unlabeled) of the single-junction photovoltaic cell assembly 112, on the bottom surface 160 of the solar panel assembly 100, is a plurality of optical redirecting/collecting unit assemblies 114. One optical redirecting/collecting unit 114d is shown as a part of the solar panel assembly 100 and another 114a is shown in an exploded view apart from the solar panel assembly 100. As can be seen in the exploded view, in this embodiment an optical redirecting/collecting unit assembly 114 (e.g. 114a) has an optical redirecting unit 116 (e.g. 116a) and an optical collecting unit 118 (e.g. 118a) (which in use are mated together). Both the optical redirecting units 116 and the optical collecting units 118 are described in further detail below.

FIG. 3 also shows the relative size relationship between an optical redirecting/collecting unit assembly 114, an optical concentrating unit 104, and a single junction photovoltaic assembly 112. As can be seen in FIG. 3, in this embodiment, the optical redirecting/collecting unit assemblies 114 are the same size as the optical concentrating units. Thus, each of the optical redirecting/collecting units 114 also has the following dimensions in this embodiment: 37.5 mm (length)×37.5 mm (width)×3 mm (depth). In this embodiment, each optical redirecting/collecting unit assembly 114 is associated with one optical concentrating unit 104. Thus, each single junction photovoltaic cell assembly 112 is associated with sixteen optical redirecting/collecting units 114. In other embodiments, the sizes and shapes of the optical redirecting/collecting units 114, the single junction photovoltaic cell assembly 112 and/or the optical concentrating units 114 (where they are present in that embodiment) will vary, as will the ratio of any to the others. No particular such sizes, shapes or ratios are required in the context of the present technology.

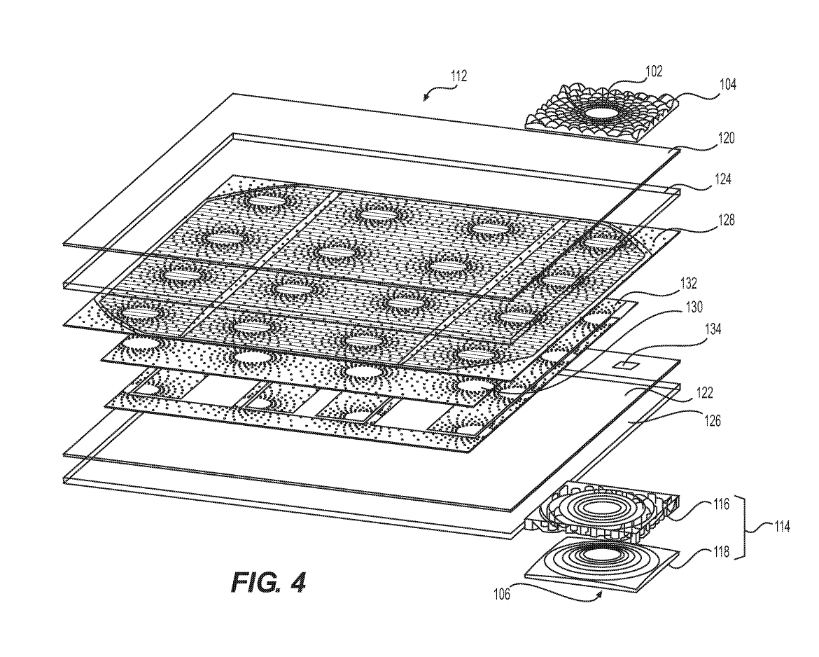

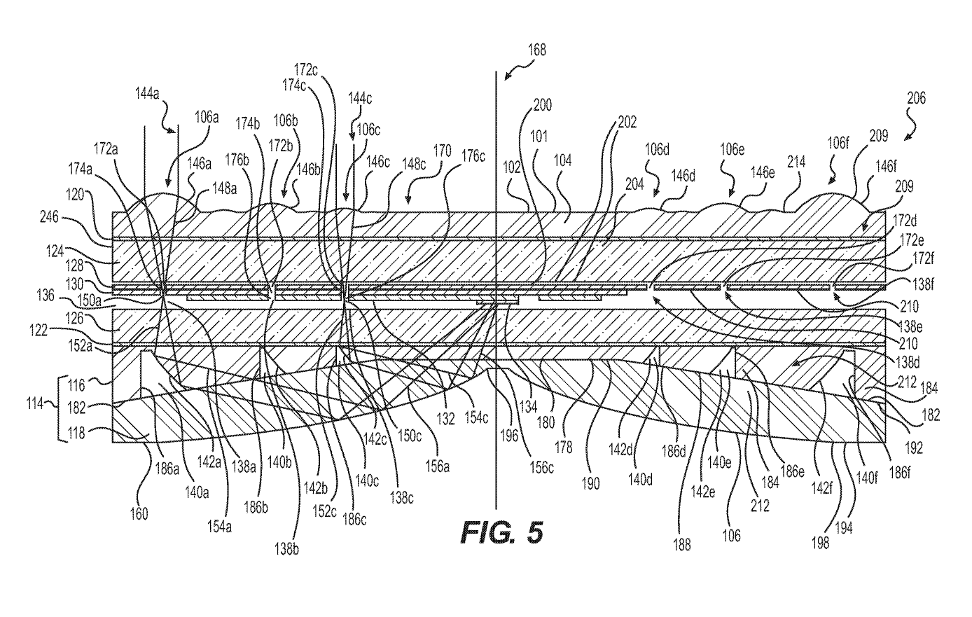

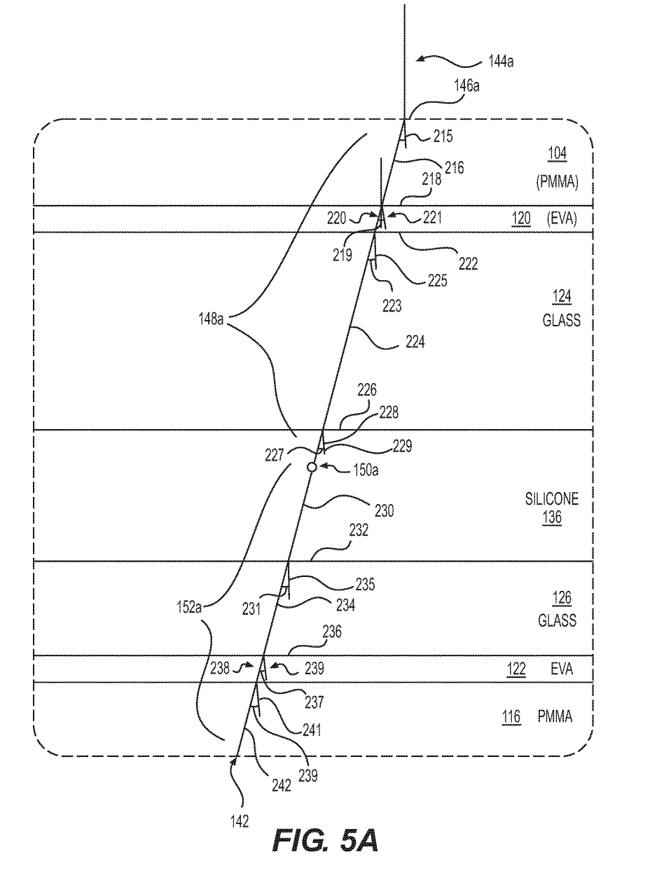

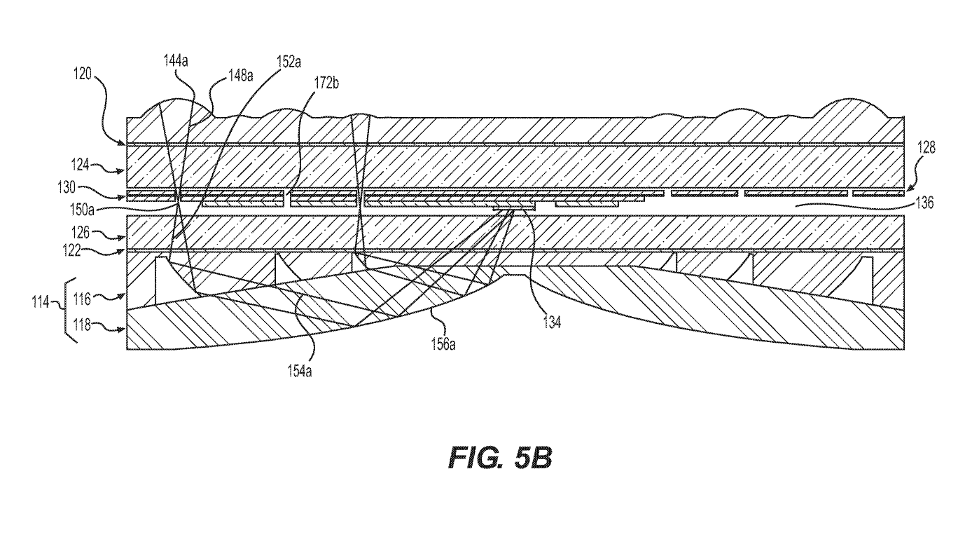

FIG. 4 shows an exploded perspective view of one of the single junction photovoltaic cell assemblies 112; along with one optical concentrating unit 104 and one optical redirecting/collecting unit 114 of the solar panel assembly 100; while FIGS. 5 (and 5B) show a partial cross-section thereof. (FIG. 5B is identical to FIG. 5 with the exception that it shows fewer reference numerals for clarity. FIG. 5B will thus not separately be referred to hereinbelow. All references to FIG. 5 herein include inherently a reference to FIG. 5B.) As can be seen in FIGS. 4 and 5, starting from the upper surface 101 of the solar panel assembly 100 and progressing to lower surface 160 of the solar panel assembly 100, in this embodiment, the solar panel assembly 100 has the following structures:

(a) optical concentrating unit 104;

(b) bonding layer 120;

(c) upper structural layer 124;

(d) flat-panel crystalline silicon single-junction photovoltaic cell 128;

(e) electrical insulator 130;

(f) electrical conductor 132;

(g) multiple-junction photovoltaic cell 134 (shown only in FIG. 5);

(h) encapsulation 136 (shown only in FIG. 5);

(i) lower structural layer 126;

(j) bonding layer 122;

(k) optical redirecting unit 116;

(l) optical collecting unit 118.

(A single junction photovoltaic cell assembly 112 of the solar panel assembly 100 includes (c) upper structural layer 124; (d) flat-panel crystalline silicon single junction photovoltaic cell 128; (e) electrical insulator 130; (f) electrical conductor 132; (g) multiple-junction photovoltaic cell 134; (h) encapsulation 136 (shown in FIG. 5); and (i) lower structural layer 126. An optical redirecting/collecting unit 114 of the solar panel assembly includes (k) optical redirecting unit 116 and (l) optical collecting unit 118.) Each of these structures is described in further detail in turn below.

### First Embodiment (Component Descriptions)

As was set forth above, in this embodiment, in the middle of the solar panel assembly 100 there is a layer 110 comprised of a plurality of flat-panel single junction crystalline silicon photovoltaic cells 128. For purposes of economic efficiency, in this embodiment, the photovoltaic cells 128 are conventional crystalline-silicon photovoltaic cells 128 such as those available from SunEdison™ of the USA, or Motech Industries Inc. of Taiwan, or Yingli Solar of China.

In other embodiments, different photovoltaic cells 128 are used, some employing the same technology as described above, others employing different technology from that described above. For example, the conventional photovoltaic cells 128 from SunEdison™ etc. described above, are conventionally used to harvest both direct and indirect sunlight. In some embodiments of the present technology, however, little direct sunlight is harvested via the photovoltaic cells 128 (as it is mostly harvested via the concentrated photovoltaic aspect of the device), therefore a single-junction crystalline silicon photovoltaic cell having been optimized for the purpose of generally harvesting diffuse sunlight is employed. In this respect, for example, the photovoltaic cell 128 could be optimized for better electrical energy generation at the lower light energy levels and current densities involved. Such optimization could involve, for example, a change in the doping and/or the metallization grid pattern (e.g. thinner bus bars 248 and grid fingers 250—shown in FIG. 3—as less electrical current would need to be handled).

In other embodiments, different types of photovoltaic cells 128 are employed, including, for example, one of the following: triple junction crystalline silicon photovoltaic cells, heterojunction photovoltaic cells, copper-indium-gallium-selenide (CIGS) photovoltaic cells, single layer thin film photovoltaic cells, multi-layer thin film photovoltaic cells. As the purpose of these photovoltaic cells 128 is to harvest mostly diffuse light (and some direct light), any photovoltaic cell suitable for this purpose employing any suitable technology could be used.

In this embodiment, the photovoltaic cells 128 have a plurality of openings 172 therein. (It should be understood that in the present description, with a view to reducing complexity, where the context warrants, a reference number, e.g. 172, may be used generically to cover various specificities, e.g. 172a, 172b, 172c, etc.) The openings 172 are circular in cross-section (in a plane normal to the direct sunlight 144) and extend the entire depth of the photovoltaic cell 128, and thus have a 3D shape of a right circular cylinder, having a diameter of 0.3 mm. The openings 172 are formed by laser drilling holes through the photovoltaic cells 128 after their manufacture. In other embodiments, other suitable techniques, such as chemical etching or mechanical machining can be used to form the openings 172. The openings 172 are sized and arranged to allow focused direct light 148 to pass through the photovoltaic cell 128 as is described in further detail below.

On the lower side (unlabelled) of the photovoltaic cell 128 is an electrical insulator 130. In the present embodiment the electrical insulator 130 is layer of aluminum oxide (Al₂O₃), having the following dimensions: 150 mm (length)×150 mm (width)×0.1 mm (depth). In other embodiments the electrical insulator 130 could be a layer of: silicon dioxide (SiO₂), poly-methyl-methacrylate (PMMA), poly-tetrafluoroethylene (PTFE), ethylene tetrafluoroethylene (ETFE), biaxially-oriented polyethylene terephthalate (BoPET—“Mylar”™), an air gap, etc. In still other embodiments the electrical insulator 130 could be any suitable material capable of serving as an electrical insulator (whether in layer form or otherwise) that is not otherwise incapable of use in a solar panel assembly 100. In some embodiments the electrical insulator 130 could be a sheet of material having the same length and width as the solar panel assembly 100, while in other embodiments the electrical insulator 130 can be a plurality of sheets to insulate each individual photovoltaic cell 128. In still other embodiments, the electrical insulator 130 could be a material that is applied and allowed to cure directly in the solar panel assembly 100.

The primary purpose of the electrical insulator 130 is to electrically insulate the electrical conductor 132 (described in further detail below) from the photovoltaic cell 128. In other embodiments, the electrical insulator 130 may have any other shape and/or dimension sufficient to carry out its intended insulating purpose.

In this embodiment, the electrical insulator 130 has a series of openings 174 therein. The openings 174 are circular in cross-section (in a plane normal to the direct sunlight 144) and extend the entire depth of the electrical insulator 130, and thus have a 3D shape of a right circular cylinder, having a diameter of 0.3 mm. The openings 174 are aligned with the openings 172 of the photovoltaic cell 128, together forming, in this embodiment, a series of single right circular cylinders in 3D shape. In this embodiment, the openings 174 are formed by chemical etching in the electrical insulator 130. In other embodiments, the electrical insulator is transparent and no openings are present in the insulator 130 as the focused direct light 148 simply passes therethrough.

On the lower side (unlabelled) of the electrical insulator 130, is an electrical conductor 132. In the present embodiment, the electrical conductor 132 is formed of strips of copper (Cu) having the same dimensions as the photovoltaic cell 128. In other embodiments, the electrical conductor 132 could be formed of strips of aluminum (Al), silver (Ag) or gold (Au), or an otherwise suitable alloy of any of the foregoing metals. In still other embodiments, the electrical conductor 132 is any suitable material capable of serving as an electrical conductor (whether in strip form or otherwise) that is not otherwise incapable of use in a solar panel assembly 100.

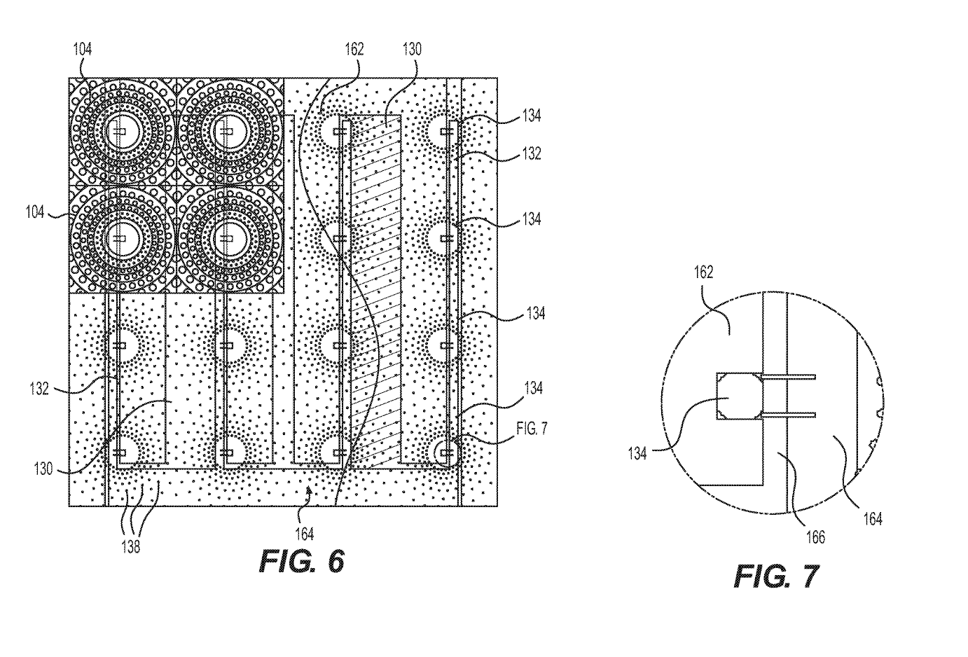

FIG. 6 shows a plan view of the electrical conductor 132 and portions of the electrical insulator 130. As can be seen in FIG. 6, the electrical conductor 132 is shaped to form two different current paths 162, 164 of an electrical circuit (unlabeled) that includes the multiple-junction photovoltaic cells 134 associated with the photovoltaic cell 128. The electrical circuit has “positive” current path 162 connected to the positive terminal (unlabelled) of each of the multiple-junction photovoltaic cells 134 and a “negative” current path connected to the negative terminals 166 of each of the multiple junction photovoltaic cells 134 (see also FIG. 7 showing a close-up view of these connections).

The electrical conductor 132 has a series of openings 176 therein. The openings 176 are circular in cross-section (in a plane normal to the direct sunlight 144) and extend the entire depth of the electrical conductor 132, and thus have a 3D shape of a right circular cylinder, having a diameter of 0.3 mm. The openings 176 are aligned with the openings 174 of the electrical insulator; in this embodiment, together with the openings 172, both forming a series of single right circular cylinders in 3D shape. In this embodiment, the openings 176 are formed by chemical etching in the electrical conductor 132.

While in the present embodiment each of the multiple-junction photovoltaic cells 134 associated with the single photovoltaic cell 128 are connected together via a single electrical circuit, this is not required to be the case. In other embodiments, not all multiple-junction photovoltaic cells 134 or any particular grouping of multiple-junction photovoltaic cells 134 (e.g. those associated with a single photovoltaic cell 128) are connected together via a single electrical circuit. In other embodiments, multiple electrical circuits (having separate electrical paths) connect various multiple junction photovoltaic cells 134. While in the present embodiment the electrical conductor 132 is in the form of strips joined together to form the current paths 162, 164, this is not required to be the case. In other embodiments, the electrical conductor 132 may have other shapes and dimensions sufficient to carry out its intended conducting purposes.

A series of passages 138 (138a, 138b, 138c, 138d, 138e, 138f—shown in FIG. 5) through the photovoltaic cell 128 (and the electrical insulator 130 and the electrical conductor 132—as the case may be) are formed by the various aligned openings 172, 174, 176 therein (as the case may be). In this embodiment, the passages 138 have the 3D shape of a right circular cylinder. (In other embodiments, the passages 138 will have different shapes, sizes, and/or lengths.) The passages 138 are filled with the material forming the encapsulation 136, which is described in further detail herein below. Referring to FIG. 5, in this embodiment, passages 138d, 138e, 138f are formed solely by openings 172d, 172e, 172f (respectively) in the photovoltaic cell 128 (there being no portion of the electrical insulator 130 nor any portion of the electrical conductor 132 underneath the photovoltaic cell 128 in the vicinity of the openings 172d, 172e, 172f). Passage 138a is formed by opening 172a in the photovoltaic cell 128 and by opening 174a in the electrical insulator 130 (openings 172a and 174a are aligned with each other) (there being no portion of the electrical conductor 132 underneath the electrical conductor 130 in the vicinity of the opening 174a). Passages 138b, 138c are formed by openings 172b, 172c (respectively) in the photovoltaic cell 128 and by openings 174b, 174c (respectively) in the electrical insulator 130 which are aligned with openings 172b, 172c (respectively), and by openings 176b, 176c (respectively) in the electrical conductor 132 which are aligned with openings 174b, 174c (respectively).

In this embodiment, multiple-junction photovoltaic cells 134 are multiple-junction GaInP/GaInAs/Ge (III-V) photovoltaic cells having the following overall dimensions: 1 mm (length)×1 mm (width). In other embodiments, other multiple junction photovoltaic cells are used. For example, in some embodiments a multiple-junction photovoltaic cell of 2 mm (length)×2 mm (width) may be employed, while in other embodiments a multiple-junction photovoltaic cell 3 mm (length)×3 mm (width) may be employed.

In this embodiment, the electrical insulator 130, the electrical conductor 132, and the multiple-junction photovoltaic cells 134 are encapsulated in an encapsulation 136, for protective, structural, and insulation purposes. Further, as was discussed above, the passages 138 are completely filled with the material of the encapsulation 136.

In this embodiment, the encapsulation 136 is a polymerized siloxane material (e.g. silicone). In other embodiments, the encapsulation 136 is a carbon-based polymer (e.g., PMMA, PTFE, ETFE, BoPET, etc.), an insulant (e.g. Al₂O₃), or a copolymer (e.g. EVA). In still other embodiments, no encapsulation is present and the electrical insulator 130, the electrical conductor 132, and the multiple junction photovoltaic cells 134 are in an air layer within the solar panel assembly. In still other embodiments, the encapsulation may be made of the same material and as a single component with the optical bonding layer 120 (described in further detail below).

In this embodiment, the photovoltaic cell 128, the electrical insulator 130, the electrical conductor 132, the multiple-junction photovoltaic cells 134, and the encapsulation 136 are sandwiched between two structural layers, an upper structural layer 124 and a lower structural layer 126. The structural layers 124, 126 serve to provide structure and rigidity to the solar panel assembly 100. In this embodiment, the both of the structural layers 124, 126 are sheets of soda-lime-silica glass. The upper structural layer 124 having the following dimensions: 1.65 m (length)×0.5 m (width)×4 mm (depth). The lower structural layer 126 having the following dimensions: 1.64 m (length)×0.49 m (width)×1.6 mm (depth). In this embodiment, the lower structural layer 126 is of a smaller depth for ease of assembly. In other embodiments, sheets of other types of glass (e.g. vitreous silica glass, sodium borosilicate glass, lead-oxide glass, aluminosilicate glass, oxide glass, etc.) not otherwise incompatible with their use in a solar panel assembly are used. In still other embodiments, the structural layers 124, 126 could be made of any otherwise appropriate transparent polymer (in sheet form or otherwise suitable form). Although in this embodiment the structural layers 124, 126 are made of the same material, this is not required. In other embodiments the structural layers 124, 126 could be made of different materials. The structural layers 124, 126 in other embodiments are of different dimensions. The structural layers 124, 126 need only be appropriately sized and dimensioned to carry out their intended function.

In this embodiment, as was discussed above, there are sixteen optical concentrating units 104 above and bonded to the upper structural layer 124 (the upper sheet of glass). As in this embodiment each of the optical collecting units 104 are identical, only one will be discussed. (There is no requirement that the optical collecting units—where present—be identical and in other embodiments the optical collecting units present will differ.) In this embodiment, each optical concentrating unit 104 is made of transparent injection-molded PMMA. In other embodiments, an optical concentrating unit 104 (where present) can be made of any otherwise appropriate light-transmissive material. Non-limiting examples include poly-methyl-methacrylimide (PMMA), polycarbonates, cyclo-olefin-polymers (COP), cyclo-olefin-copolymers (COC), PTFE, glasses, etc. The method of manufacturing could vary (depending on the material); e.g. in some embodiments casting or embossing are used.

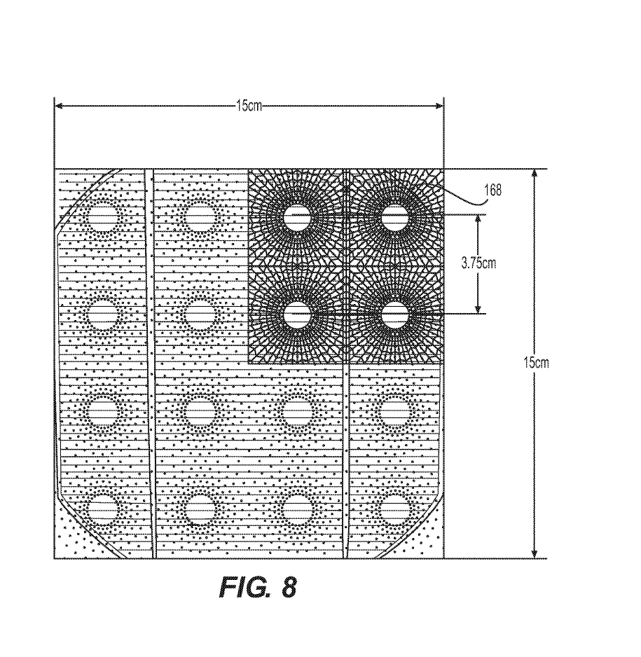

Referring to FIGS. 3, 5 and 8, in this embodiment, in the center of the upper surface 102 (along the central axis 168) of the optical collecting unit 104 (which in this embodiment forms the upper surface 101 of the solar panel assembly 100) is a flat portion 170 which is intended to be normal to direct sunlight 144 when the solar panel 100 assembly is in use. Vertically below this flat portion 170 is the multiple-junction photovoltaic cell 134. When viewed from above, the flat portion 170 is in the shape of a circle. Surrounding the flat portion 102 are lenses 106. Lenses 106 are arranged in a series of circles 172a, 172b, 172c, etc. (starting closest to the flat portion and moving outward) having a common center (along the central axis 168), being the center of the optical concentrating unit 104. In this embodiment, the lenses 106 of the circle 172a closest to the flat portion 170 all have a common diameter Dₐ (when viewed from above). The lenses 106 of the circle 172b immediately outward from the circle 172a all have a common diameter D_{b} that is greater than Dₐ. The lenses 106 of the circle 172c immediately outward from the circle 172b all have a common diameter D_{c} that is greater than D_{b}. This trend of increasing diameters Dₓ continues as one progresses away from the flat portion 170. Lenses 106 that meet the edge surface 246 of the optical concentrating unit 104 are “cut-off” by the edge surface 246 and are only partial structures. The lower surface (unlabelled) of the optical collecting unit 104 is flat.

Referring to FIG. 5 each of the lenses 106 of the optical concentrating unit 104 is shaped to have a focal point 150 through the photovoltaic cell 128 (and electrical insulator 130 and electrical conductor 132—as the case may be) at the exit of a passage 138 in the encapsulation 136. Further each lens 106 and its associated passage 138 are cooperatively shaped and sized such that effectively all direct sunlight 144 impinging on the surface 146 of the lens 106 is focused towards the focal point 150, and all of the focused light 148 enters and traverses the passage 138 and arrives at the focal point 150. Thus, when the solar panel assembly 100 directly faces the sun, direct sunlight rays 144a impinge on the surface 146a of the lens 106a and are focused by the lens 106a (through the photovoltaic cell 128 and the electrical insulating layer 130) at focal point 150a, which is at the exit of passage 138a in the encapsulation 136 material. The focused light rays 148a traverse the remainder of the body of the lens 106a, the optical bonding layer 120 (described in further detail below), the upper structural layer 124, enter the passage 138a filled with the encapsulation 136 material, and traverse the photovoltaic cell 128 and the electrical insulating layer 130 through the passage 138a, and arrive at the focal point 150a of lens 106a. Similarly, direct sunlight rays 144c impinge on the surface 146c of the lens 106c and are focused by the lens 106c (through the photovoltaic cell 128, the electrical insulating layer 130, and the electrical conducting layer 132) at focal point 150c, which is at the exit of passage 138c in the encapsulation 136 material. The focused light rays 148c traverse the remainder of the body of the lens 106c, the optical bonding layer 120, the upper structural layer 124, enter the passage 138c, and traverse the photovoltaic cell 128, the electrical insulating layer 130, and the electrical conducting layer, through the passage 138c, and arrive at the focal point 150c of lens 106c.

In this embodiment, there is a transparent bonding layer 120 that bonds the optical concentrating units 104 to the upper surface (unlabelled) of the upper structural layer 124. The bonding layer 120 is sufficiently elastically deformable to accommodate shear stress developed as a result of changes in temperature of the solar panel assembly 100 and the difference (if any) between the coefficient of thermal expansion of the material of which the optical concentrating unit 104 is made and the coefficient of thermal expansion of the material of which the upper structural layer 124 is made. In this embodiment, the transparent bonding layer 120 is made of ethylene vinyl acetate (EVA). In other embodiments, the transparent bonding layer (if present) could be made of polymerized siloxane (e.g. silicone), polyvinyl acetate (PVA), any otherwise suitable ionomer, etc. (A note on thermal expansion: The passages 138 are sized and shaped such that they can accommodate a shift in the focal point of their associated lenses 106 owing to the differences in the coefficients of thermal expansion referred to above. In addition, the multiple-junction photovoltaic cells 134 are of a sufficient size such that minor changes to the light ray paths that occur because of the differences in the coefficients of thermal expansion referred to above are accommodated. In this embodiment the optical concentrating units 104 and the optical redirecting/collecting units 114 are made of the same material. They therefore have the same coefficients of thermal expansion and thus in most cases the alignment between them will be very minimally affected, if at all.)

In this embodiment, as was discussed above there are sixteen optical redirecting/collecting units 114 below and bonded to the lower structural layer (lower sheet of glass) 126. As in this embodiment each of the optical redirecting/collecting units 114 are identical only one will be discussed. (There is no requirement that the optical redirecting/collecting units 114—where present—be identical and in other embodiments the optical collecting units present will differ.) In this embodiment, each optical redirecting/collecting unit 114 has two components, an (upper) optical redirecting unit 116 and a (lower) optical collecting unit 118, each of which is a 37.5 cm square unit (when viewed from above) having a depth of 3 mm made of transparent injection-molded PMMA. In other embodiments, an optical redirecting unit 116 and an optical collecting unit 118 (where present) can be made of any otherwise appropriate light-transmissive material. Non-limiting examples include poly-methyl-methacrylimide (PMMA), polycarbonates, cyclo-olefin-polymers (COP), cyclo-olefin-copolymers (COC), PTFE, glasses, etc. The redirecting/collecting unit 114 has a depth of 6 mm. In this embodiment the redirecting units 116 and the optical collecting units 118 are bonded together with an optical adhesive such as silicone. (Not shown in the figures.) In other embodiments, the redirecting units 116 and the optical collecting units 118 may be injection molded as a single piece to form the redirecting/collecting units 114. The method of manufacturing could vary (depending on the material); e.g. in some embodiments casting or embossing are used.

Referring to FIGS. 3, 4 and 5, in this embodiment, the upper surface (unlabelled) of the optical redirecting unit 116 is flat. The central portion 180 of the lower surface 178 of the optical redirecting unit 116 is flat (when viewed from the side) and is generally the same size and shape (e.g. a circle) as the central portion 170 of the upper surface 102 of the optical concentrating unit 104 (when viewed from below). Extending from the central portion 180, the lower surface 178 has a rotationally-symmetric (but for being cut off by the square-shaped edge surfaces) downwardly-sloping planar portion 182 (i.e. forming the surface of a right circular conical frustum in 3D). Extending upwardly from the planar portion 182 of the lower surface 178 into the body 184 is a series of crescent-shaped (when viewed from below) recesses 140. The recesses 140c/140d closest to the flat central portion 180 are the smallest in both area and depth and the recesses 140 grow larger in both area and depth the further they are from the central portion 180. The area of each recess 140 decreases along its depth progressing away from the lower surface 178. The edge surfaces 142 of each recess 140 that face the central portion 180 is a portion of a circular paraboloid (whose particular shape is described below in further detail). The edge surfaces 186 of each recess 140 opposite the paraboloidal-portion surfaces 142 are a portion of an outer surface of right circular cylinder. In this embodiment, air fills each recess 140.

In this embodiment, the upper surface 188 of the optical collecting unit 118 is generally complimentary to (with the exception of the recesses 140) and registers with the lower surface 178 of the optical redirecting unit 116. Thus, the upper surface 188 of the optical collecting unit 118 has a central flat portion 190 that is complimentary in size and shape to the central flat portion 180 of the lower surface 178 of the optical redirecting unit 116. Extending from the central portion 190, the upper surface 188 has a rotationally-symmetric (but for being cut off by the square-shaped edge surfaces) downwardly-sloping planar portion 192 (i.e. forming the surface of a right circular conical frustum in 3D). The downwardly-sloping planar portion 192 of the upper surface 188 of the optical collecting unit 118 is generally complimentary in size and shape (with the exception of the recesses 140) to the downwardly-sloping planar portion 182 of the lower surface 178 of the optical redirecting unit 116. When the optical collecting unit 118 is mated with (and bonded to) the optical redirecting unit 116 to form optical redirecting/collecting unit 114, the downwardly-sloping planar portion 192 of the upper surface 188 of the optical collecting unit 118 closes the recesses 140 in the downwardly-sloping planar portion 182 of the lower surface 178 of the optical redirecting unit 116 retaining the air in the recesses 140.

In this embodiment, the lower surface 194 of the optical collecting unit 118 (which forms a part of the lower surface 160 of the solar panel assembly 100) has a flat (when viewed from the side) central portion 196, which is smaller in size than the flat central portion 190 of the upper surface 188 of the optical collecting unit 118. Extending from the central portion 196, the lower surface 194 has a rotationally-symmetric (but for being cut off by the square-shaped edge surfaces) upwardly-facing curved portion 198. The curved portion 198 has the shape of surface of revolution formed by revolving a section of a parabola about an axis, whose particular shape is described below in further detail.

In this embodiment, there is a transparent bonding layer 122 that bonds the optical redirecting units 116 to the lower surface (unlabelled) of the lower structural layer 126. The bonding layer 122 is sufficiently elastically deformable to accommodate shear stress developed as a result of changes in temperature of the solar panel assembly 100 and the difference (if any) between the coefficient of thermal expansion of the material of which the optical redirecting unit 116 is made and the coefficient of thermal expansion of the material of which the lower structural layer 126 is made. In this embodiment, the transparent bonding layer 122 is made of ethylene vinyl acetate (EVA). In other embodiments, the transparent bonding layer (if present) is made of polymerized siloxane (e.g. silicone), polyvinyl acetate (PVA), any otherwise suitable ionomer, etc. In this embodiment, bonding layer 122 is made of the same material as bonding layer 120; however in other embodiments bonding layer 122 is made of a different material than bonding layer 120. The bonding layer 122 has the following dimensions 1.65 m (length)×0.50 m (width)×400 μm (depth).

### First Embodiment (Light Paths)

Referring to FIG. 5, once the focused light rays 148 arrive at and traverse the focal point 150 of the lens 106, the light rays 152 begin to diverge as they travel away from the focal point 150. The diverging light rays 152 traverse the remainder of the encapsulation 136, the lower structural layer 126, the bonding layer 122, and the body 184 of the optical redirecting unit 116. The divergent light rays 152 impinge upon the curved edge surface 142 of a recess 140. Curved edge surface 142 acts as reflector that functions on the basis of total internal reflection owing to the difference between the refractive index of the PMMA of the body 184 of the optical redirecting element 116 and the refractive index of the air in the recess 140. The divergent light rays 152 reflect off the curved edge surface 142 back into the body 184 of the optical redirecting unit 116 and are redirected (owning to the shape of the curved edge surface 142) towards the curved portion 198 of the lower surface 194 of the optical collecting unit 118. The redirected light rays 154 traverse the body 184 of the optical redirecting unit 116 and the body (unlabelled) of the optical collecting unit 118. The redirected light rays 154 impinge upon the curved portion 198 of the lower surface 194 of the optical collecting unit 118. Curved portion 198 acts as a reflector that functions on the basis of total internal reflection owing to the difference between the refractive index of the PMMA of the body of the optical collecting unit 118 and the refractive index of the ambient air below the lower surface 194 of the optical collecting unit 118. The redirected light rays 154 reflect off the curved portion 198 back into the body of the optical collecting unit 118 towards the multiple-junction photovoltaic cell 134 (as collected light rays 156—owing to the shape of the curved portion 198). The collected light rays 156 traverse the body of the optical collecting unit 118, the body 184 of the optical redirecting unit 116, the bonding layer 122, the lower structural layer 126, the encapsulation 136 and impinge upon the multiple-junction photovoltaic cell 134 for harvesting.

As was discussed above, in this embodiment, the curved edge surface 142 of each recess 140 in the lower surface 178 of the optical redirecting element 116 (which acts as a reflector) has the shape of an off-axis portion of a paraboloid. The curved portion 198 of the lower surface 194 of the optical collecting element 118 (which also acts a reflector) has the shape of a section of a parabola rotated around an axis of revolution (collinear with the central axis 168) perpendicular to the axis of the parabola used to create a surface of revolution. Each of these surfaces 142, 198 has its own particular position (within the unit 116, 118 of which it is a part), shape and orientation such that the diverging focused direct light 152 follows an optical path from a focus 150 to the multiple-junction photovoltaic cell 134 as was described hereinabove.

Thus, continuing with the above example, in this embodiment, when the solar panel assembly 100 directly faces the sun, direct sunlight rays 144a impinge on the surface 146a of the lens 106a and are focused by the lens 106a (through the photovoltaic cell 128 and the electrical insulating layer 130) towards focal point 150a, which is at the exit of passage 138a. The focused light rays 148a traverse the remainder of the body of the lens 106a, the optical bonding layer 120, the upper structural layer 124, enter the encapsulation 136 material within the passage 138a, and traverse the photovoltaic cell 128 and the electrical insulating layer 130 through the passage 138a, and arrive at the focal point 150a of lens 106a in the encapsulation 136. From the focal point 150a, the diverging focused light rays 152a traverse the remainder of the encapsulation 136, the lower structural layer 126, the optical bonding layer 122, and the body 184 of the optical directing element 116 and impinge upon the curved edge surface 142a of recess 140a in the lower surface 178 of the optical redirecting unit 116. The curved edge surface 142a is positioned, sized, shaped and orientated such that the light rays 152a reflect off the curved edge surface 142a in a direction parallel to the axis of the paraboloid defining shape of the curved edge surface 142a. (The axis of the paraboloid is not shown in FIG. 5 although it is generally parallel to the light rays 154a shown reflecting off the curved edge surface 142a. In this embodiment, the focus of the paraboloid is designed to be coincident with the focus of the lens 150a. As can be seen in FIG. 5, however, when the solar assembly 100 is in use, owing to several factors including thermal expansion of the various components of the solar assembly 100, the focus of the paraboloid is very slightly off from the focus of the lens 106a. This causes the light rays 154a in FIG. 5 to appear to be slightly convergent. At other points in time in the solar panel assembly's 100 use, the light rays 154a might appear to be slightly divergent.)

The (now) redirected light rays 154a traverse the body 184 of the optical redirecting element 116 and the body of the optical collecting element 118 and impinge on the curved portion 198 of the lower surface 194 of the optical collecting element 118. The curved edge portion 198 is positioned, shaped and orientated such that the light rays 154a reflect off curved portion 198 towards the focus of the parabola defining the shape of the curved portion 198. In this embodiment, the focus is not shown in FIG. 5 although it is above (and behind, relative to the light path) the multiple-junction photovoltaic cell 134. In other embodiments, the focus of the parabola defining the shape of the curved portion 198 is located at the center of the bottom face or on the bottom face of the multiple-junction photovoltaic cell 134. The (now) collected light rays 156a traverse the body of the optical collecting element 118, the optical redirecting element 116, the bonding layer 122, the lower structural layer 126, the encapsulation 136 and impinge upon the multiple-junction photovoltaic cell 134, which the light rays 156a enter for harvesting.

Similarly, in this embodiment, direct sunlight rays 144c impinge on the surface 146c of the lens 106c and are focused by the lens 106c (through the photovoltaic cell 128, the electrical insulating layer 130 and the electrical conducting layer 132) towards focal point 150c, which is at the exit of passage 138c. The focused light rays 148c traverse the remainder of the body of the lens 106c, the optical bonding layer 120, the upper structural layer 124, enter the encapsulation material within the passage 138c, and traverse the photovoltaic cell 128, the electrical insulating layer 130, and the electrical conducting layer, through the passage 138c, and arrive at the focal point 150c of lens 106c in the encapsulation. From the focal point 150c, the diverging focused light rays 152c traverse the remainder of the encapsulation 136, the lower structural layer 126, the optical bonding layer 122, and the body 184 of the optical directing element 116 and impinge upon the curved edge surface 142c of recess 140c in the lower surface 178 of the optical redirecting unit 116. The curved edge surface 142c is positioned, sized, shaped and orientated such that the light rays 152c reflect off the curved edge surface 142c parallel to the axis of the paraboloid defining the shape of the curved edge surface 142c. (The axis of the paraboloid is not shown in FIG. 5 although it is generally parallel to the light rays 154c shown reflecting off the curved edge surface 142c. In this embodiment, the focus of the paraboloid is designed to be coincident with the focus of the lens 150c. As can be seen in FIG. 5, however, when the solar assembly 100 is in use, owing to several factors including thermal expansion of the various components of the solar assembly 100, the focus of the paraboloid is very slightly off from the focus of the lens 106c. This causes the light rays 154c in FIG. 5 to appear to be slightly divergent. At other points in time in the solar panel assembly's 100 use, the light rays 154c might appear to be slightly convergent.)

The (now) redirected light rays 154c traverse the body 184 of the optical redirecting element 116 and the body of the optical collecting element 118 and impinge on the curved portion 198 of the lower surface 194 of the optical collecting element 118. The curved edge portion 198 is positioned, sized, shaped and orientated such that the light rays 154c reflect off curved portion 198 towards the focus of the parabola defining the shape of the curved portion 198. In this embodiment, the focus is not shown in FIG. 5 although it is above (and behind, relative to the light path) the multiple-junction photovoltaic cell 134. In other embodiments, the focus of the parabola defining the shape of the curved portion 198 is located at the center of the bottom face or on the bottom face of the multiple-junction photovoltaic cell 134. The (now) collected light rays 156c traverse the body of the optical collecting element 118, the optical redirecting element 116, the bonding layer 122, the lower structural layer 126, the encapsulation 136 and impinge upon the multiple-junction photovoltaic cell 134, which the light rays 156c enter for harvesting. (The optical collecting unit 118 is termed a “collecting” unit as, in this embodiment, the light rays 154 that have been redirected by any of the reflectors formed by the curved edge surfaces 142 of any of the recesses 140 are all reoriented towards the multiple junction photovoltaic cell 134 by the curved portion 198 of the lower surface 194 of the optical collecting unit 118, thus “collecting” thus light rays 154.)

Still referring to FIG. 5, in this embodiment, direct light rays 200 that impinge upon the upper surface 102 of the solar panel assembly 100 that do not impinge upon a lens 106 impinge upon the central flat portion 170 or a portion 214 between the lenses 106 of the upper surface 102 of an optical concentrating unit 104. Because their angle of incidence with the upper surface 102 is 90°, no refraction occurs (notwithstanding the difference between the index of refraction of the ambient air above the upper surface 102 and the index of refraction of the PMMA of the optical concentrating unit 104). Thus, in thus embodiment, such direct light rays 200 continue straight through the upper surface 102 and traverse the optical concentrating unit 104, the bonding layer 120, the upper structural layer 124, and impinge upon the photovoltaic cell 128 for harvesting. Thus, in the present embodiment, not all of the direct light rays impinging on the solar panel array 100 are harvested via a multiple-junction photovoltaic cell 134; some direct light rays 200 are harvested via a single-junction photovoltaic cell 128.

Still referring to FIG. 5, in this embodiment, diffuse light rays 202, 206 that impinge upon the upper surface 102 of the optical concentrating unit 104 impinge either on the central flat portion 170a, a portion 214 between the lenses 106, or on one of the lens surfaces 146 of a lens 106. Diffuse light rays 202 infringing upon the central flat portion 170a or a portion 214 are refracted upon entry into the body of the optical concentrating element 104 (owing to the difference between the index of refraction of the ambient air above the upper surface 102 and the index of refraction of the PMMA of the optical concentrating unit 104). Resultant refracted light rays 204 traverse the optical concentrating unit 104, the boding layer 120, the upper layer structural 124, and impinge upon the photovoltaic cell 128 for harvesting. Diffuse light rays 206 infringing upon the surface 146 (e.g. 146f) of a lens 106 (e.g. 106f) are also refracted upon entry into the body of the optical concentrating element 104 (owing to the difference between the index of refraction of the ambient air above the upper surface 102 and the index of refraction of the PMMA of the optical concentrating unit 104). Resultant refracted light rays 208 traverse the optical concentrating unit 104, the boding layer 120, the upper layer structural 124, and impinge upon the photovoltaic cell 128 for harvesting.

Still referring to FIG. 5, in this embodiment, the solar panel assembly 100 is capable of harvesting some diffuse albedo light rays. In this respect, diffuse albedo light ray 210 has resulted from a light ray having been reflected off a background surface behind (underneath) the solar panel assembly 100. Diffuse albedo light rays 210 impinge upon the curved portion 198 of the lower surface 194 of the optical collecting unit 118. Diffuse albedo light rays 210 are refracted upon entry into the body of the optical collecting unit element 118 (owing to the difference between the index of refraction of the ambient air below the lower surface 194 and the index of refraction of the PMMA of the optical collecting unit 118). Resultant refracted light rays 212 traverse the body of the optical collecting unit 118, and either solely the body 184 of the optical redirecting element 116 or the body 184 of the optical redirecting element 116 and the air pocket created by a recess 140 (as the case may be), and the bonding layer 122, the lower structural layer 126, the encapsulation 136 and then impinge on the photovoltaic cell 128 for harvesting.

As a person skilled in the art would understand, FIG. 5 is not granular enough to show the refractive changes in the light paths as the light rays progress from one material to another once inside the solar panel assembly 100. Those light paths appear in FIG. 5 to be straight lines as if the various components had the same refractive index, when in actuality the paths are not straight lines as the various components have different refractive indices (albeit in the same range). In this respect, the refractive index of PMMA is 1.49469626; the refractive index of silicone is 1.40654457; the refractive index of glass: 1.51947188; and the refractive index of EVA is 1.49370420. The refractive index of air is 1.00027

FIG. 5A is a schematic view of a portion of the light path of a direct sunlight ray 144a impinging on lens 106a as described above. FIG. 5A illustrates the effect of the difference in the refractive indices of the various components. The aforementioned example with direct light ray 144a will be used. Direct light ray 144a is refracted at the lens surface 146a because of the difference between the refractive indices of air (1.00027) and PMMA (1.49469626), and is focused toward the focal point 150a of the lens 106a. The angle of incidence 215 is 14.6945°. The focused refracted light ray 148a in FIG. 5, (which is considered as a single linear light ray in that figure) is illustrated in FIG. 5A as separate light rays 216, 220, 224, and 228, each of which are described in turn.

Focused light ray 216 traverses the body of the optical concentrating unit 104 to the boundary 218 between the optical concentrating unit 104 and the bonding layer 120. Light ray 216 is refracted at the boundary 218 because of the difference between the refractive indices of PMMA (1.49469626) and EVA (1.49370420) as light ray 220. The effective angle of incidence 219 is 14.7074°. (The effective angle of incidence 219 is the angle between the light ray 220 and a line 221 parallel to direct light ray 144a.)

Light ray 220 traverses the bonding layer 120 to the boundary 222 between the bonding layer 120 and the upper structural layer 124. Light ray 220 is refracted at the boundary 222 because of the difference between the refractive indices of EVA (1.49370420) and glass (1.51947188) as light ray 224. The effective angle of incidence 223 is 14.4477°. (The effective angle of incidence 223 is the angle between the light ray 224 and a line 225 parallel to direct light ray 144a.)

Light ray 224 traverses the upper structural layer 124 to the boundary 226 between the upper structural layer 124 and the encapsulation 136 material within the passage 138a. Light ray 224 is refracted at the boundary 226 because of the difference between the refractive indices of glass (1.51947188) and silicone (1.40654457) as light ray 228. The effective angle of incidence 227 is 15.6097°. (The effective angle of incidence 227 is the angle between the light ray 228 and a line 229 parallel to direct light ray 144a.) Light ray 228 traverses the passage 138 and traverses the focal point 150a of the lens 160a. In FIG. 5, at this point, the focused refracted light ray 148a in FIG. 5 (which is considered as a single linear light ray in that figure) traverses the focal point 150a and leaves as light ray 152a in FIG. 5 (which is also considered as a single linear light ray in that FIG. 5). FIG. 5A, however, is far more granular and light ray 228 traverses the focal point 150a and is light ray 230.

Light ray 230 traverses the encapsulation 136 to the boundary 232 between the encapsulation 136 and the lower structural layer 126. Light ray 220 is refracted at the boundary 232 because of the difference between the refractive indices of silicone (1.40654457) and glass (1.51947188) as light ray 234. The effective angle of incidence 231 is 15.6045°. (The effective angle of incidence 231 is the angle between the light ray 234 and a line 235 parallel to direct light ray 144a.)

Light ray 234 traverses the lower structural layer 126 to the boundary 236 between the lower structural layer 126 and bonding layer 122. Light ray 234 is refracted at the boundary 236 because of the difference between the refractive indices of glass (1.51947188) and EVA (1.49370420) as light ray 238. The effective angle of incidence 237 is 14.1470°. (The effective angle of incidence 237 is the angle between the light ray 238 and a line 239 parallel to direct light ray 144a.)

Light ray 238 traverses bonding layer 122 to the boundary 240 between the bonding layer 122 and the optical redirecting unit 116. Light ray 238 is refracted at the boundary 240 because of the difference between the refractive indices of EVA (1.49370420) and PMMA (1.49469626) as light ray 242. The effective angle of incidence 237 is 14.6583°. (The effective angle of incidence 239 is the angle between the light ray 242 and a line 241 parallel to direct light ray 144a.)

Light ray 242 traverses the body 184 of the optical redirecting unit 116 to the curved edge surface 142a of the recess 140a. Light ray 242 reflects off the curved edge surface 142 as was described hereinabove.

It should be understood that although not able to be illustrated in FIG. 5 because of the lack of granularity, the solar panel assembly 100 and its various components (as with other embodiments of the present technology) are designed to take into account the slight deviations from a straight line of the actual path the light rays take through the solar panel assembly, an example of a portion of which is illustrated in FIG. 5A.

### First Embodiment (Method of Manufacture)

Methods of manufacturing solar panel assembly 100, include, but are not limited to, the following: Appropriately sized single junction photovoltaic cells 128 are obtained from a manufacturer thereof (such as one of those referred to in the background section of this specification). Material suitable for forming the electrical insulating layer 130 is applied to photovoltaic cells 128 via any suitable combination of direct deposition techniques or growth techniques (such as forming silicon-oxide layers on the cell 128), or by attaching an insulating thin sheet or film of polymeric material to the photovoltaic cells 128 via any of adhesive, heat and/or pressure.

In some methods, the electrical conductor 132 is pre-assembled with the electrical insulator 130 to form one single component that is later attached to the photovoltaic cells 128 as was described above. In some such methods, the electrical conductor 132 is a polymer film with electrical conductor traces, where the film serves as an insulating layer 130 and the traces serve as the conductor 132.

In some methods, the electrical conductor 132 is formed directly on the insulator 130, by a metal deposition techniques or film application techniques such as sputtering, screen printing, printing, or electrochemically forming.

In some methods, material suitable for forming the electrical conductor 132 is placed on the electrical insulating layer 130.

In some methods, insulator 130 is formed as an integral part of the photovoltaic cells 128.

In some methods, the photovoltaic cell 128, the insulating layer 130 and the electrical conductor 132, once assembled would form one solid component.

The electrical conductor 132 electrically interconnects the multiple-junction photovoltaic cells 134. In some methods, the multiple-junction photovoltaic cells 134 are assembled onto the electrical conductor 132 prior to assembly of the insulator 130 with the electrical conductor 132 and the photovoltaic cells 128. In other methods, the multiple-junction photovoltaic cells 134 are assembled onto the electrical conductor 132 after the previously mentioned assembly in sequence. In either case, the multiple-junction photovoltaic cells 134 can be pre-packaged (with wire bonds onto a common semiconductor package or lead frame) to allow for surface mount soldering of the multiple-junction photovoltaic concentrator cells to the underlying conductor.

The photovoltaic cells 128 and the multiple-junction photovoltaic cells 134 are then electrically interconnected together. This is conventional manner appropriate for silicon PV cells using solder ribbon to create strings of photovoltaic cells 128 where the ribbon conductors will ultimately be combined to a connector or terminator inside of a junction box.

Solder ribbon can also be used to create strings of multiple junction photovoltaic cells 134 by creating electrical interconnections between the electrical conductors 132, creating larger strings and ultimately providing a path for electricity outside of the module through a junction box. The electrical circuit connecting the photovoltaic cells 128 can be completely independent of the electrical circuit connecting the multiple-junction photovoltaic cells 134, with both having terminals inside the same or in different junction boxes. In the latter case, the module would have two positive and two negative terminals and would act electrically as two independent modules with different current and voltage characteristics and different efficiencies under various illumination conditions. This would therefore be a four terminal assembly 100 and the power from the two electrically independent modules within the whole module would be combined at some point in the electrical system or used to power separate loads.

It is also possible to make each module into a two terminal device by using embedded electronics to perform a DC-DC conversion of any, some or all of the multiple-junction photovoltaic cells 134 and the photovoltaic cells 128 to make it efficient to connect the different cells in parallel or in series. Electronics can be embedded at a module level, at the string level, or at the photovoltaic cells 128 level.

Once the electrical circuits with terminals have been created for the photovoltaic cells 128 and the multiple-junction photovoltaic cells 134, the whole assembly (consisting of single junction photovoltaic cells 128, insulator 130, conductor 132, and multiple junction photovoltaic cells 134) are laminated between the upper structural layer 124 (e.g. glass) and the lower structural layer 126 (e.g. glass). This lamination can be done by curing a transparent silicone material between two sheets of structural layers 124 and 126 with the other elements in place or by reflowing a polymer such as EVA. The lamination process leaves an encapsulation material 136 which envelopes the components (single-junction photovoltaic cells 128, insulator 130, conductor 132, and multiple-junction photovoltaic cells 134) inside the sandwich between the two structural layers 124 and 126.

For example, the encapsulation 136 (silicone in this embodiment) can be placed over the electrical conductor 132 and the lower structural layer 126 is placed thereof, sandwiching the single-junction photovoltaic cells 128, the electrical insulator 130, the electrical conductor 132, the multiple-junction photovoltaic cells 134, and the encapsulation 136 between the upper 124 and lower 126 structural layers.

Bonding layer 120 (e.g. silicone or EVA) is applied to the free surface of the upper structural layer 124 and the optical concentrating units 104 are placed thereon adhering them to the upper structural layer 124.

Bonding layer 122 (e.g. silicone or EVA) is applied to the free surface of the lower structural layer 126 and the optical redirecting/collecting units 114 are placed thereon adhering them to the lower structural layer 126. The optical collecting unit 118 and the optical redirecting unit 116 can be made integrally out of one piece of formed polymer to create 114 or they can be an assembly of individually formed pieces bonded together.

### Second Embodiment

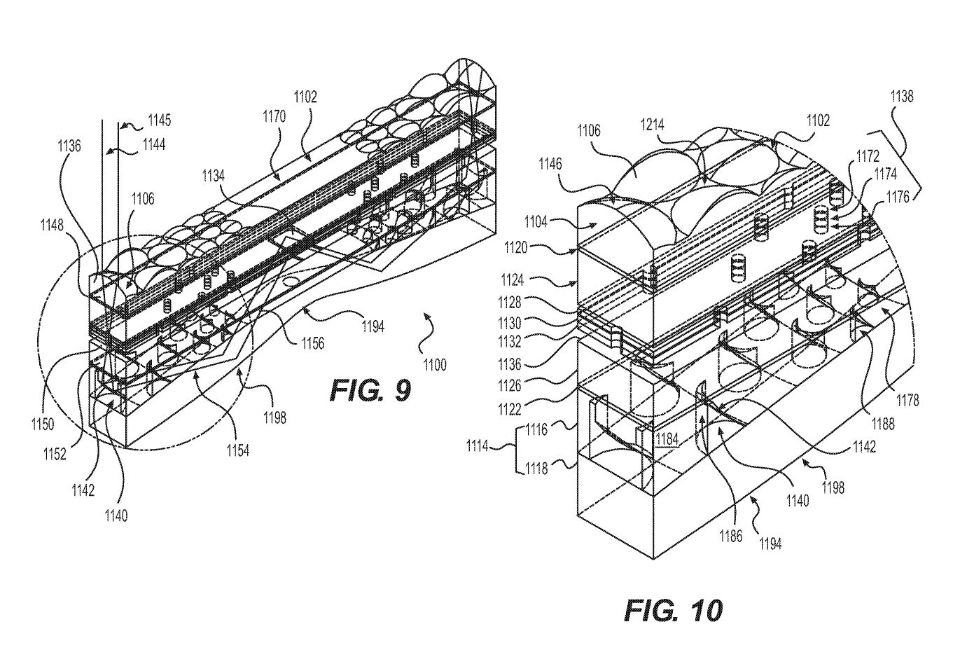

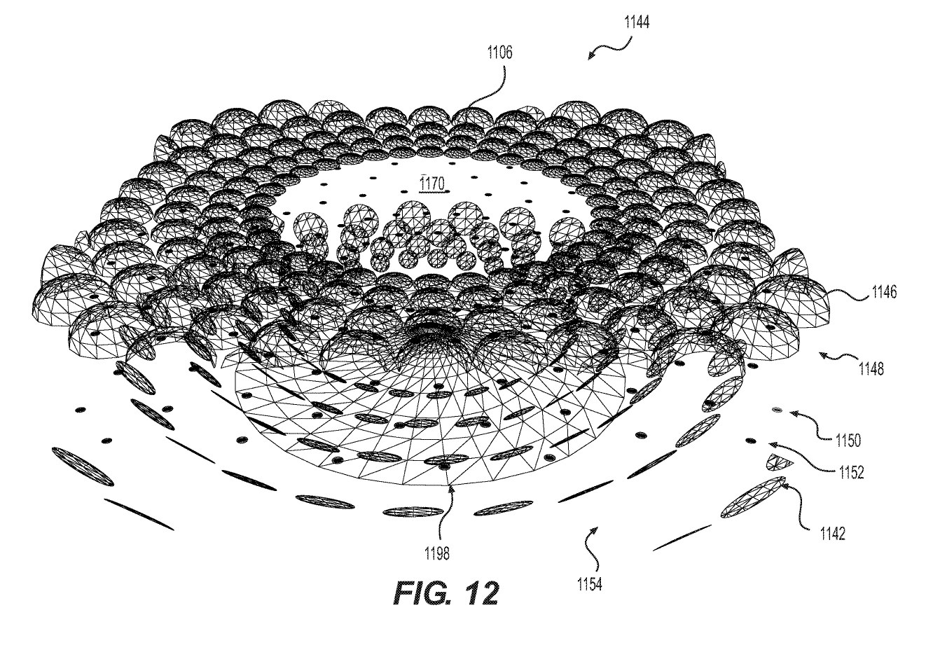

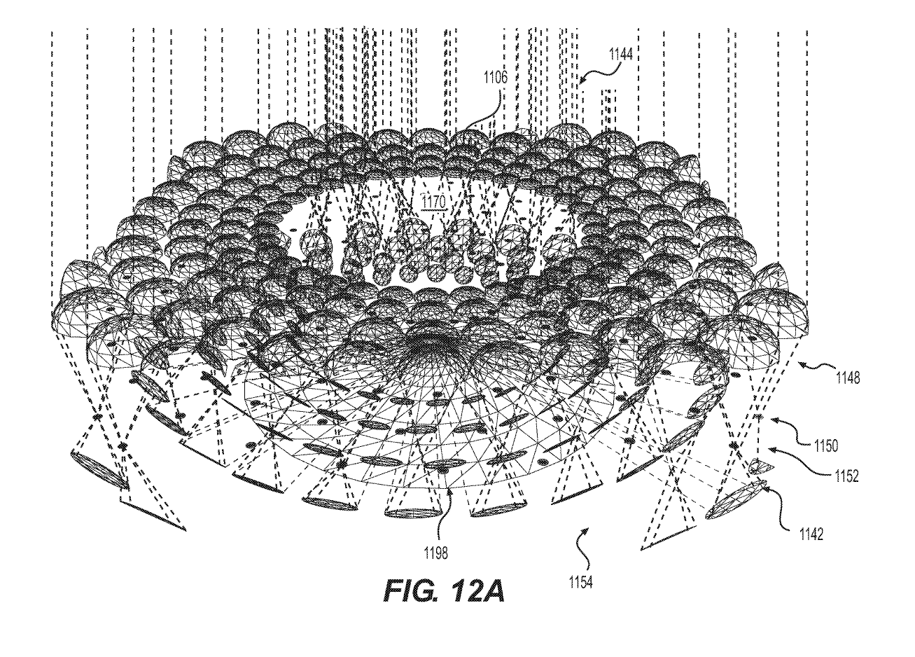

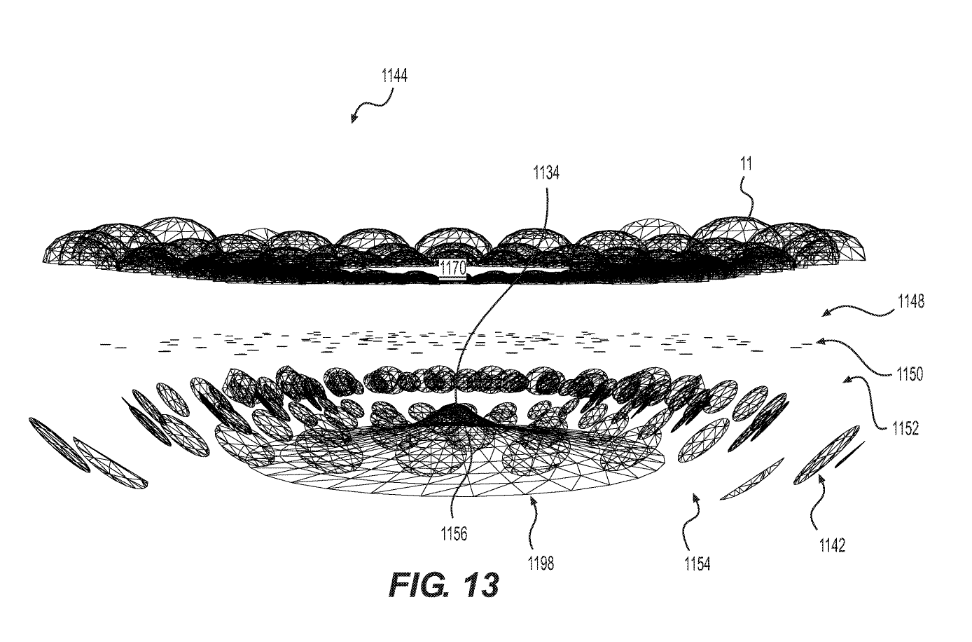

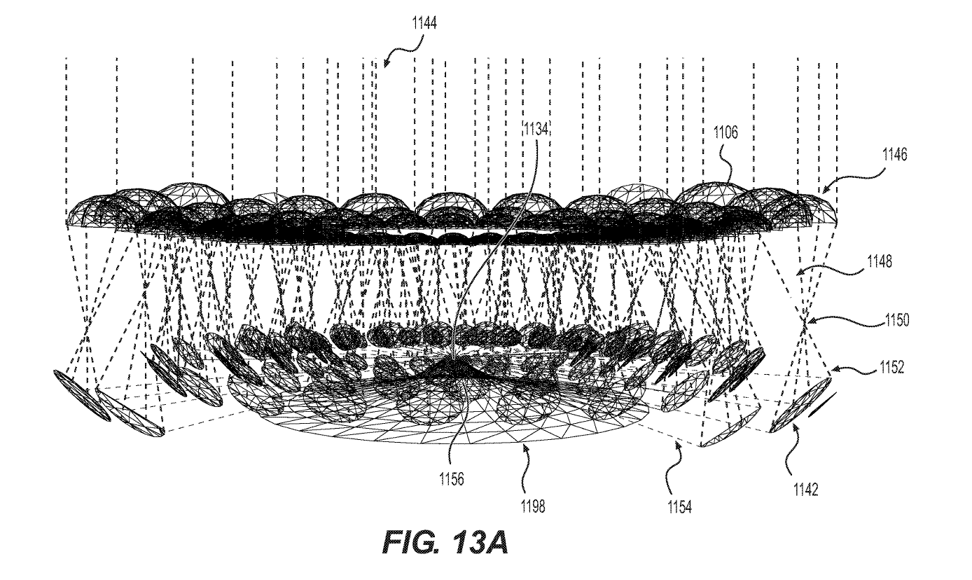

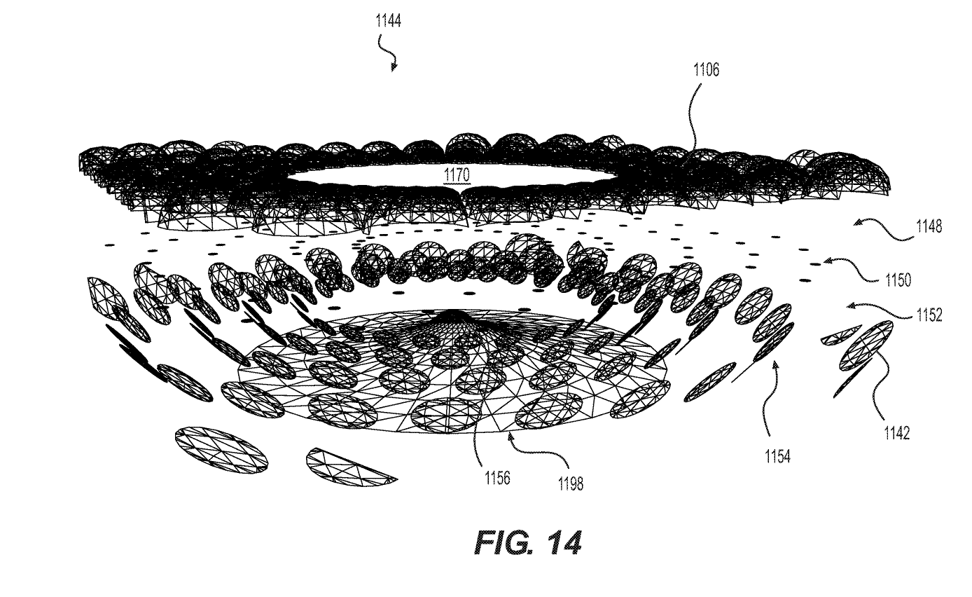

For ease of understanding, the first embodiment—solar panel assembly 100—was described with reference to a two-dimensional cross-section (e.g. FIG. 5) of the solar panel assembly 100, showing light rays travelling within the plane of that cross-section. While some actual light rays do indeed follow these paths, the solar panel assembly 100 is a three-dimensional device. Light rays thus travel in directions other than those illustrated in FIG. 5. Thus, with reference to FIG. 9-15, a second embodiment, a section of a solar panel assembly 1100, is illustrated in three-dimensions to provide additional understanding of the present technology.

Referring to FIGS. 9 and 10, solar panel assembly 1100 is similar to solar panel assembly 100, with some differences. In particular the lenses 1106 on the upper surface 1102 of the optical concentrating units 1104 of solar panel assembly 1100 are arranged in five and (a portion of a sixth) concentric circles (as opposed to in three concentric circles as was the case with solar panel 100). Similarly, the optical directing units 1116 of the optical redirecting/collecting units 1114 of solar panel assembly 1100 have additional recesses 1140 to cooperate with the additional lenses 1106 of the optical concentrating units 1104. Similarly, there are additional passages 1138 through which the direct sunlight rays 1144 are focused in view of the additional lenses 1106 of the optical concentrating units 1104.

Referring particularly to FIG. 10, solar panel assembly 1100 has optical concentrating units 1104 made of PMMA. The upper surface 1102 of each optical concentrating unit 1104 has a series of lenses 1106 arranged in concentric circles. In between each of the lenses 1106 are flat portions 1214. In the center of the upper surface 1101 of each optical concentrating unit 1104 is a central circular flat portion 1170. Each lens 1106 has a convex lens surface 1146 (which is three-dimensionally illustrated in FIGS. 9 and 10). The optical concentrating units 1104 are bonded to an upper structural layer 1124 made of a sheet of glass by a bonding layer 1120 of EVA. Sandwiched between upper structural layer 1124 and lower structural layer 1126 (which is also a sheet of glass) are single-junction photovoltaic cells 1128, an electrical insulator 1130, an electrical conductor 1132, multiple-junction photovoltaic cells 1134, and encapsulation 1136. (Each of these components is similar to their counterparts in solar panel assembly 100 and will not be described in further detail herein.) The single-junction photovoltaic cells 1128, the electrical insulator 1130, and the electrical conductor 1132 each have a series of holes (1172, 1174, 1176 respectively) therein, together forming optical passages 1138.

Optical redirecting/collecting units 1114 of PMMA are bonded to the lower structural surface 1126 by a bonding layer 1122 of EVA. Optical redirecting/collecting units 1114 each comprise an optical redirecting unit 1116 and an optical collecting unit 1118. Extending upwards from the lower surface 1178 of each of the optical redirecting units 1116 into the body 1184 thereof are a series of recesses 1140, which are filled with air. Each recess 1140 has a curved edge surface 1142 (having the shape of a portion of a paraboloid) and an edge surface 1186 opposite the edge surface 1142 having the shape of a portion of a right circular cylinder. Below the optical redirecting unit 1116 is an optical collecting unit 1118 (also of PMMA) that has an upper surface 1188 sealing the lower surface 1178 of the corresponding optical redirecting unit 1116, and a lower surface 1194 having a curved portion 1198 (having the shape of a revolved section of a parabola). Each of the structures described herein have a similar structure, function, and methods of assembly and use as with respect to their counterparts in solar panel assembly 100 and will not be described in further detail herein.

Referring to FIG. 9, the path of a direct sunlight ray 1144 through solar panel assembly 1100 can be seen. In particular FIG. 9 illustrates such path in three-dimensions. Direct sunlight ray 1144 impinges on the surface 1146 of one of the lenses 1106 and is focused (as light ray 1148) towards the focus 1150 of the lens 1106, which is at the exit of the passage 1138 in the encapsulation 1136. Traversing the focus 1150 (as light ray 1152), light ray 1152 continues to travel through the solar panel assembly 1100 and impinges upon the paraboloidal edge surface 1142 of a recess 1140. Light ray 1152 reflects off the paraboloidal edge surface 1142 because of total internal reflection and is reflected as light ray 1154 parallel to the axis (not shown) of the paraboloid defining the paraboloidal edge surface 1142. Light ray 1154 continues to travel through the solar panel assembly 1100 and impinges upon the revolved parabolic curved portion 1198 of the lower surface 1194 of the optical collecting unit 1118. Light ray 1154 reflects off the revolved parabolic curved portion 1198 because of total internal reflection and is reflected as light ray 1156 towards the focal point (not shown—but located above and near the multiple-junction photovoltaic cell 1134) of the parabola defining the revolved parabolic curved portion 1198. Light ray 1156 continues to travel through the solar panel assembly 1100 and impinges on the multiple-junction photovoltaic cell 1134 for harvesting thereby.

Also shown in FIG. 9 is a second light direct ray 1145 and the path that it takes through the solar panel assembly 1100 to the multiple-junction photovoltaic cell 1134.

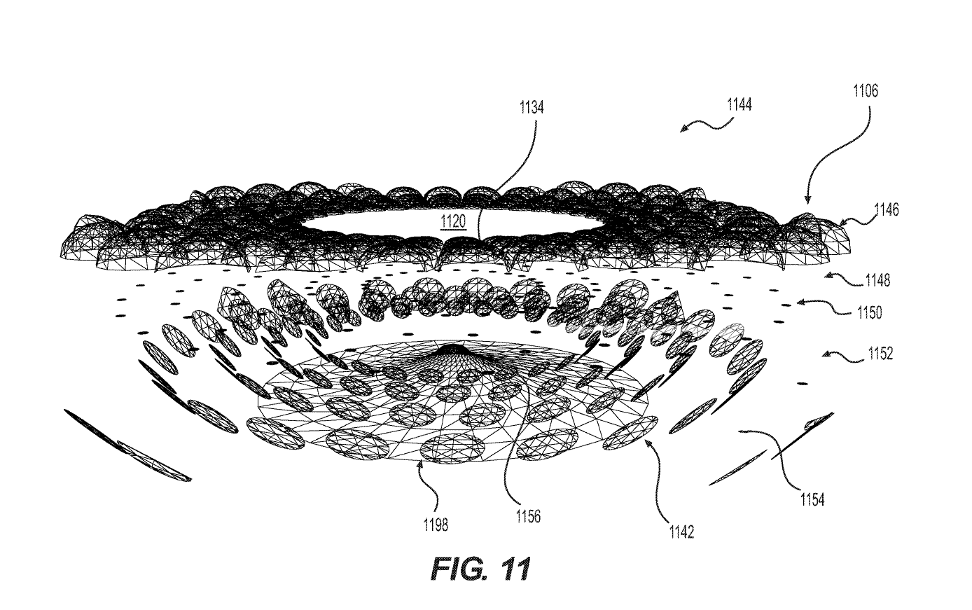

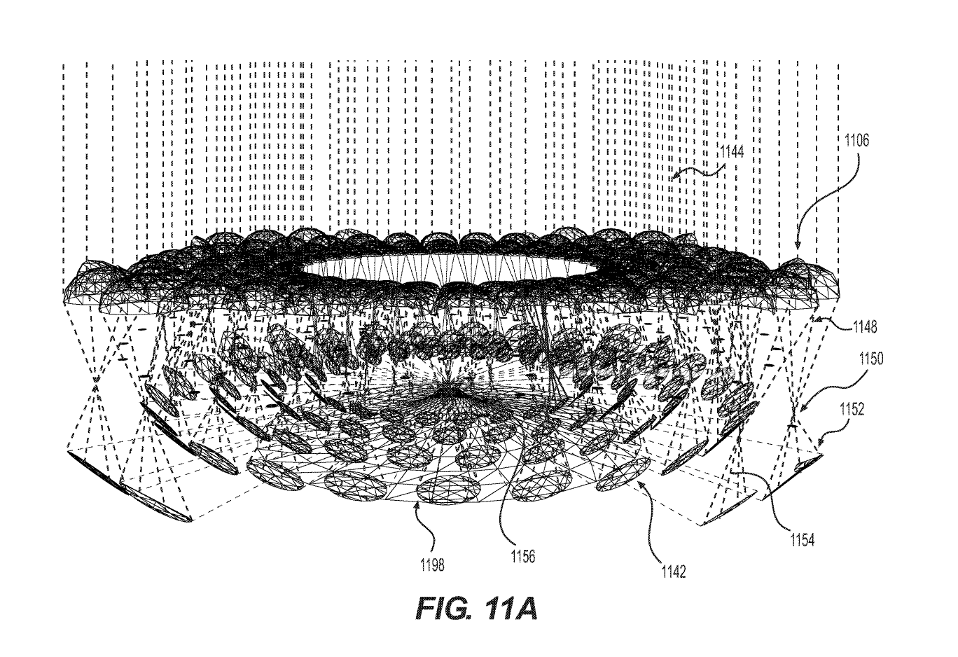

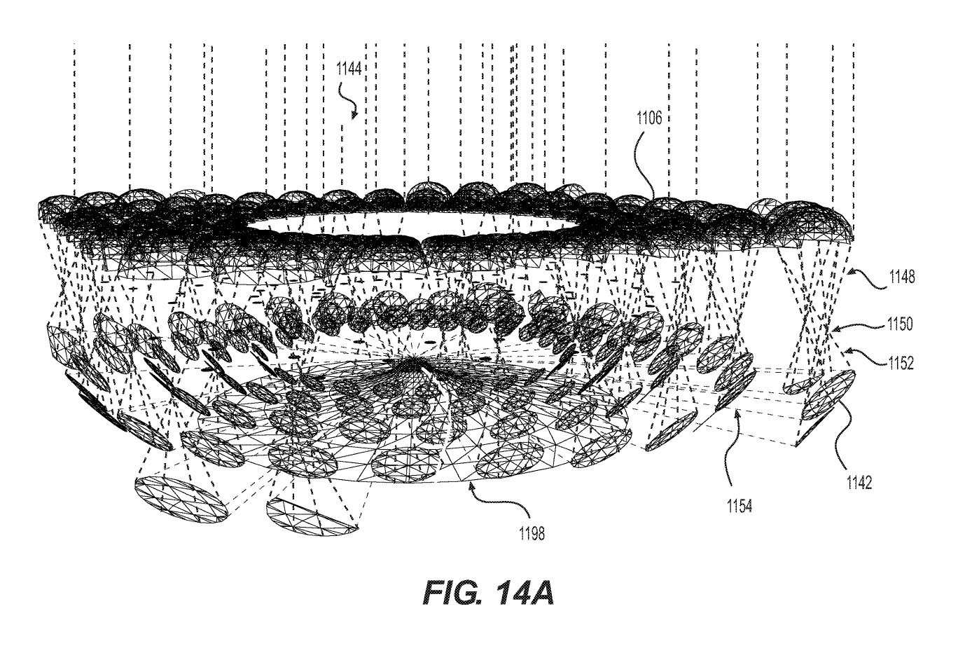

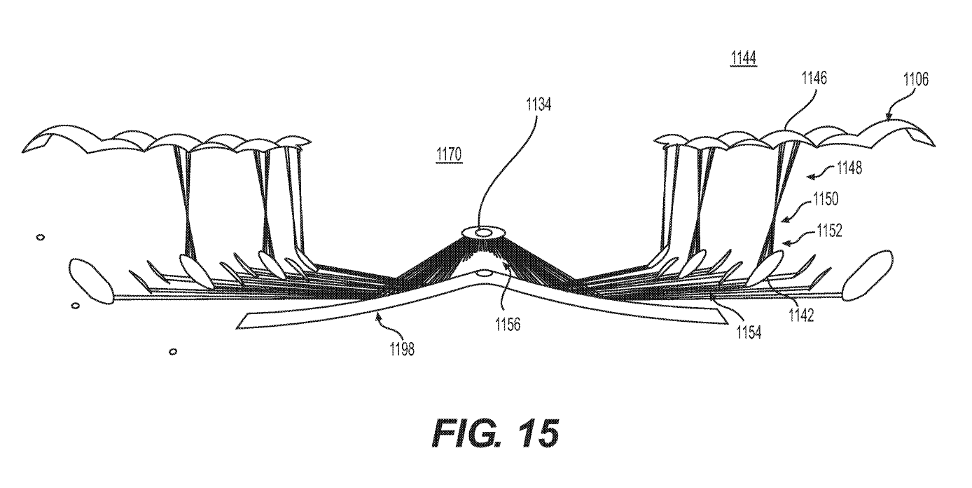

FIGS. 11, 11A, 12, 12A, 13, 13A, 14, 14A and 15 assist in providing additional understanding of the present embodiment. FIG. 15 provides a schematic view illustrating the paths taken by a multitude of direct lights rays 1144 impinging on a section of a optical concentrating unit 1104 of the solar panel assembly 1100 similar to that in FIGS. 9 and 10. To facilitate understanding this schematic, most of the components of the solar panel assembly 1100 are not shown (although they are obviously present). Thus, it can be seen that direct sunlight rays 1144 impinge on the surface 1146 of one of the lenses 1106 and are focused as light rays 1148 towards the focus 1150 of that one of the lenses 1106. Traversing the focuses 1150 (as light rays 1152), light rays 1152 impinge upon one of the paraboloidal edge surfaces 1142 and are reflected because of total internal reflection as light rays 1154 parallel to the axis of the paraboloid defining that paraboloidal edge surface 1142. Light rays 1154 then impinge upon the paraboloidal curved portion 1198 and reflect off the paraboloidal curved portion 1198 because of total internal reflection as light rays 1156 towards the focal point of the paraboloidal defining the paraboloidal curved portion 1198. Light rays 1156 then impinge on the multiple-junction photovoltaic cell 1134 for harvesting thereby.

FIGS. 11-14A provide several schematic views (taken from different viewpoints) illustrating the paths taken by a multitude of direct lights rays 1144 impinging on an optical concentrating unit of the solar panel assembly 1100. Again, to facilitate understanding these schematics, most of the components of the solar panel assembly 1100 are not shown (although they are obviously present). Thus, it can be seen that direct sunlight rays 1144 impinge on the surface 1146 of one of the lenses 1106 and are focused as light rays 1148 towards the focus 1150 of that one of the lenses 1106. Traversing the focuses 1150 (as light rays 1152), light rays 1152 impinge upon one of the paraboloidal edge surfaces 1142 and are reflected because of total internal reflection as light rays 1154 parallel to the axis of the paraboloid defining that paraboloidal edge surface 1142. Light rays 1154 then impinge upon the revolved parabolic curved portion 1198 and reflect off the revolved parabolic curved portion 1198 because of total internal reflections as light rays 1156 towards the focal point of the parabola defining the revolved parabolic curved portion 1198. Light rays 1156 then impinge on the multiple-junction photovoltaic cell 1134 for harvesting thereby.

In this embodiment, direct light rays (not shown) impinging upon the central flat portion 1170 of the upper surface 1102 of the optical collecting unit 1104 of the solar panel assembly 1100 impinge upon the single-junction photovoltaic cell 1128 (shown only in FIGS. 9-10) for harvesting.

No diffuse light rays have been shown imping upon the solar panel assembly 1100 in FIGS. 9-15 in order to facilitate understanding. As was described above with respect to the first embodiment, in this embodiment, such light diffuse light rays would generally ultimately impinge about the single-junction photovoltaic cell 1128 for harvesting.

### Third Embodiment

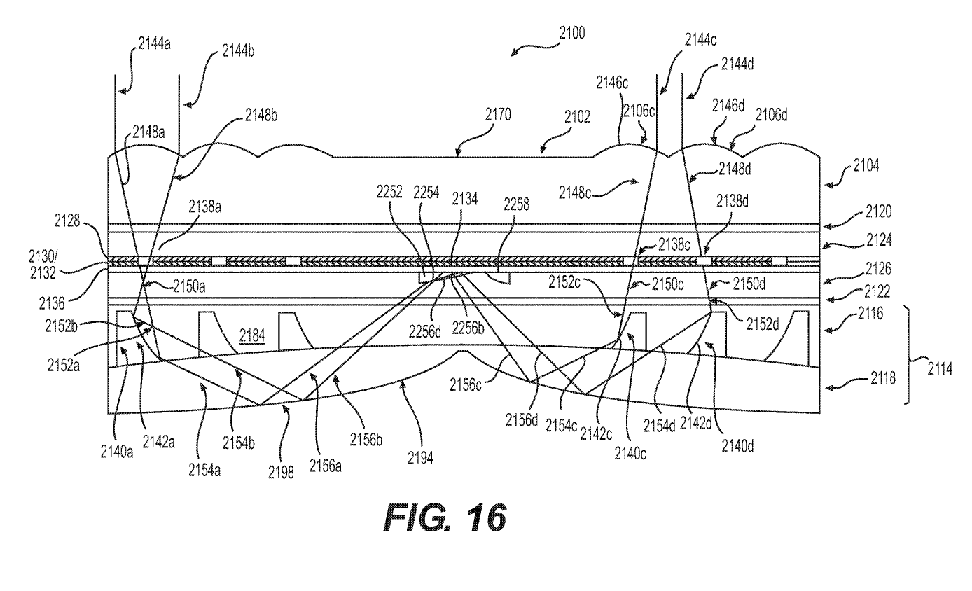

Referring to FIG. 16, there is illustrated a third embodiment, solar panel assembly 2100, shown in cross-section. Solar panel assembly 2100 is similar to solar panel assembly 100, with some differences. In particular, the optical collecting element of this embodiment is a compound structure, as is further described herein below.

Solar panel assembly 2100 has optical concentrating units 2104 of PMMA. The upper surface 2102 of each optical concentrating unit 2104 has a series of lenses 2106 arranged in concentric circles. In the center of the upper surface 2102 of each optical concentrating unit 2104 is a central circular flat portion 2170. Each lens 2106 has a convex lens surface 2146. The optical concentrating units 2104 are bonded to an upper structural layer 2124 (made of a sheet of glass) by bonding layer 2120 of EVA. Sandwiched between upper structural layer 2124 and lower structural layer 2126 (which is also a sheet of glass) are single-junction photovoltaic cells 2128, an electrical insulator 2130, an electrical conductor 2132 (illustrated for simplicity in FIG. 16 as a single layer), multiple-junction photovoltaic cells 2134, and encapsulation 2136. In this embodiment, the upper surface 2258 has a ring-shaped recess 2252 (when viewed from above) therein surrounding the multiple-junction photovoltaic cell 2134. The ring-shaped recess 2252 has a curved bottom surface 2254 being parabolic in cross section. (Each of these components is otherwise similar to their counterparts in solar panel assembly 100 and will not be described in further detail herein.) The single junction photovoltaic cells 2128, the electrical insulator 2130, and the electrical conductor 2132 each have a series of holes forming optical passages 2138.

Optical redirecting/collecting units 2114 of PMMA are bonded to the lower structural surface 2126 by a bonding layer 2122 of EVA. Optical redirecting/collecting units 2118 each comprise an optical redirecting unit 2116 and an optical collecting unit 2114. Extending upwards from the lower surface 2178 of each of the optical redirecting units 2116 into the body 2184 thereof are a series of recesses 2140, which are filed with air. Each recess 2140 has a curved edge surface 2142 (having the shape of a portion of a paraboloid) and an edge surface 2186 opposite the edge surface 2142 having the shape of a portion of a right circular cylinder. Below the optical redirecting unit 2116 is an optical collecting unit 2118 (also of PMMA) that has an upper surface 2188 sealing the lower surface 2178 of the corresponding optical redirecting unit 2116, and a lower surface 2194 having a curved portion 2198 (having the shape of a portion of a paraboloid). Each of the structures described herein have a similar structure, function, and methods of assembly and use as with respect to their counterparts in solar panel assembly 100 and will not be described in further detail herein.

In FIG. 16, the path of direct sunlight rays 2144 through solar panel assembly 2100 can be seen. In this respect, certain direct sunlight rays 2144c,d have a path that is similar to that of the path of the direct light rays 144 shown in FIG. 5. Thus, direct sunlight rays 2144c,d impinge on the surface 2146c,d (respectively) of one of the lenses 2106c,d (respectively) and are focused (as light rays 2148c,d (respectively)) towards the focus 2150c,d (respectively) of the lenses 2106c,d (respectively), which are at the exit of the passages 2138c,d (respectively) in the encapsulation 2136. Traversing the focus 2150c,d (respectively) (as light rays 2152c,d (respectively)), light rays 2152c,d continue to travel through the solar panel assembly 2100 and impinge upon the paraboloidal edge surfaces 2142c,d (respectively) of recesses 2140c,d (respectively). Light rays 2152c,d reflects off the paraboloidal edge surfaces 2142c,d (respectively) because of total internal reflection and are reflected as light rays 2154c,d (respectively) parallel to the axis (not shown) of the paraboloids defining the paraboloidal edge surface 2142c,d. (The focuses of the paraboloids defining the paraboloidal edge surfaces 2142c,d are in this embodiment coincident with the focus 2150c,d of the lenses 2106c,d respectively.) Light rays 2154c,d continue to travel through the solar panel assembly 2100 and impinge upon the revolved parabolic curved portion 2198 of the lower surface 2194 of the optical collecting unit 2118. Light rays 2154c,d reflect off the revolved parabolic curved portion 2198 because of total internal reflection and are reflected as light rays 2156c,d (respectively) towards the focal point (not shown—but located above and near the multiple-junction photovoltaic cell 2134) of the parabola defining the revolved paraboloic curved portion 2198. Light rays 2156c,d (respectively) continue to travel through the solar panel assembly 2100 and impinge on the multiple-junction photovoltaic cell 2134 for harvesting thereby.

However, certain direct sunlight rays 2144a,b have a path that differs slightly from the path described previously with respect to direct sunlight rays 2144c,d. Direct sunlight rays 2144a,b impinge on the surface 2146a of one of the lenses 2106a and are focused (as light rays 2148a,b (respectively)) towards the focus 2150a of the lens 2106a, which is at the exit of the passages 2138a in the encapsulation 2136. Traversing the focus 2150a (as light rays 2152a,b (respectively)), light rays 2152a,b continue to travel through the solar panel assembly 2100 and impinge upon the paraboloidal edge surface 2142a of recess 2140a. Light rays 2152a,b reflect off the paraboloidal edge surface 2142a because of total internal reflection and are reflected as light rays 2154a,b parallel to the axis (not shown) of the paraboloid defining the paraboloidal edge surface 2142a. (The focuses of the paraboloids defining the paraboloidal edge surface 2142a are in this embodiment coincident with the focus 2150a of the lens 2106a.) Light rays 2154a,b continue to travel through the solar panel assembly 2100 and impinge upon the revolved parabolic curved portion 2198 of the lower surface 2194 of the optical collecting unit 2118. Light rays 2154a,b reflect off the revolved parabolic curved portion 2198 because of total internal reflection and are reflected as light rays 2156a,b (respectively) towards the focal point (not shown—but located above the multiple-junction photovoltaic cell 2134) of the parabola defining the revolved parabolic curved portion 2198. Light rays 2156a,b (respectively) continue to travel through the solar panel assembly 2100 and impinge on the curved bottom surface 2254 of recess 2252 in the lower structure layer 2126. Light rays 2156a,b reflect off the curved bottom surface 2254 because of a mirror coating on the surface of the recess and are reflected as light rays 2256a,b (respectively) towards the multiple-junction photovoltaic cell 2134. Light rays 2256a,b (respectively) continue to travel through the solar panel assembly 2100 and impinge on the multiple-junction photovoltaic cell 2134 for harvesting thereby.

In this embodiment, direct light rays (not shown) impinging upon the central flat portion 2170 of the upper surface 2102 of the optical collecting 2104 of the solar panel assembly 2100 impinge upon the single-junction photovoltaic cell 2128.

No diffuse light rays have been shown impinging upon the solar panel assembly 2100 in FIG. 16 in order to facilitate understanding. As was described above with respect to the first embodiment, in this embodiment, such light diffuse light rays would generally ultimately impinge about the single-junction photovoltaic cell 2128 for harvesting.

### Fourth Embodiment

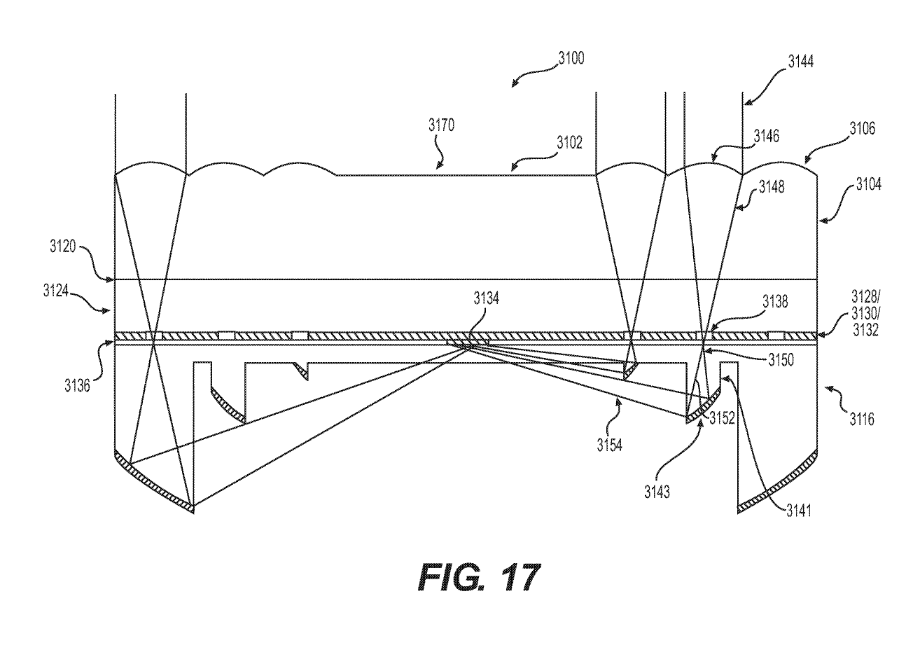

Referring to FIG. 17, there is illustrated a fourth embodiment, solar panel assembly 3100, shown in cross-section. Solar panel assembly 3100 is similar to solar panel assembly 100, with some differences. In particular, this embodiment has no optical collecting element.

Solar panel assembly 3100 has optical concentrating units 3104 of PMMA. The upper surface 3102 of each optical concentrating unit 3104 has a series of lenses 3106 arranged in concentric circles. In the center of the upper surface 3102 of each optical concentrating unit 3104 is a central circular flat portion 3170. Each lens 3106 has a convex lens surface 3146. The optical concentrating units 3104 are bonded to an (upper) structural layer 3124 (made of a sheet of glass) by bonding layer 3120 of EVA. Sandwiched between upper structural layer 3124 and an optical redirecting unit 3116 (which is in this embodiment is made of glass) are single junction photovoltaic cells 3128, an electrical insulator 3130, an electrical conductor 3132 (all illustrated for simplicity in FIG. 17 as a single layer), multiple-junction photovoltaic cells 3134, and encapsulation 3136. (Each of these components is otherwise similar to their counterparts in solar panel assembly 100 and will not be described in further detail herein.) The single-junction photovoltaic cells 3128, the electrical insulator 3130, and the electrical conductor 3132 each have a series of holes forming optical passages 3138.

Optical redirecting units 3116 each have a series of downward annular straight walled projections 3141 made of PMMA. At the lower end of each projection 3141 is a curved surface 3143, which is coated with a reflective material such as aluminium or silver to form a mirror.

In FIG. 17, the path of direct sunlight rays 3144 through solar panel assembly 3100 can be seen. Direct sunlight rays 3144 impinge on the surface 3146 of one of the lenses 3106 and are focused (as light rays 3148) towards the focus 3150 of the lenses 3106, which are at the exit of the passages 3138 in the encapsulation 3136. Traversing the focus 3150 (as light rays 3152), light rays 3152 continue to travel through optical redirecting unit 3116 and the annual projections 3141 thereof and impinge upon the parabolic mirrored surfaces 3143. Light rays 3152 reflect off the curved mirrored surfaces 3143 and are reflected as light rays 3154 towards the focal point (not shown—but appropriately located with respect to the multiple-junction photovoltaic cell 3134 such that light rays impinging thereon are focused such that they intersect the multiple-junction photovoltaic cell 3134) of the curved mirrored surface 3143. Light rays 3154 continue to travel and impinge on the multiple-junction photovoltaic cell 3134 for harvesting thereby.

In this embodiment, direct light rays (not shown) impinging upon the central flat portion 3170 of the upper surface 3102 of the optical collecting unit 3104 of the solar panel assembly 3100 impinge upon the single-junction photovoltaic cell 3128.

No diffuse light rays have been shown imping upon the solar panel assembly 3100 in FIG. 17 in order to facilitate understanding. As was described above with respect to the first embodiment, in this embodiment, such light diffuse light rays would generally ultimately impinge about the single-junction photovoltaic cell 3128 for harvesting.

### Fifth Embodiment

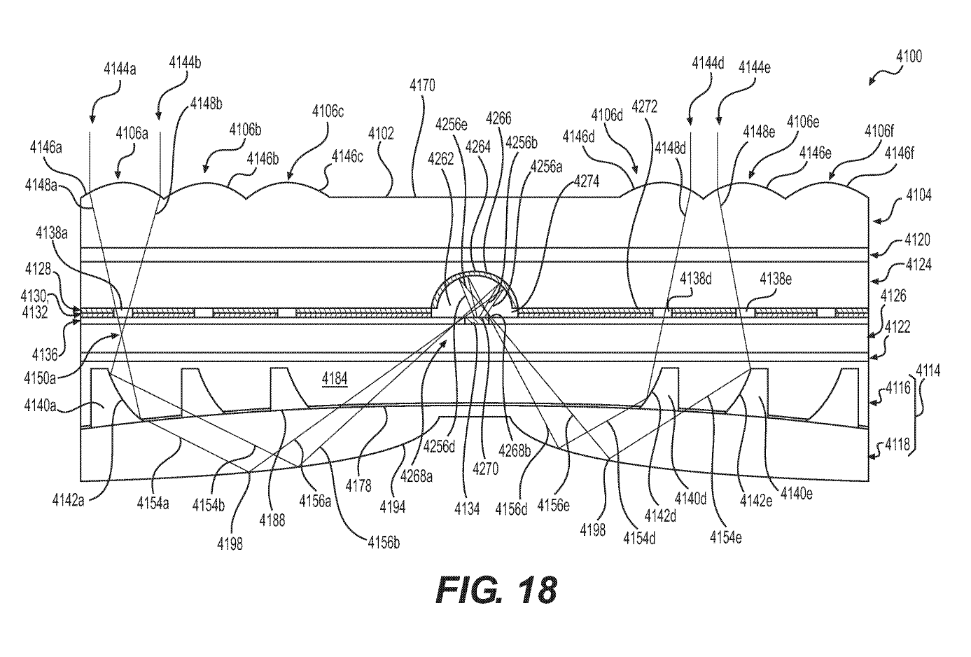

Referring to FIG. 18, there is illustrated a fifth embodiment, solar panel assembly 4100, shown in cross-section. Solar panel assembly 4100 is similar to solar panel assembly 100, with some differences. In particular, the focused collected direct rays enter the upper surface 4270 of the multiple junction photovoltaic cell 4134, as is further described herein below.

Solar panel assembly 4100 has optical concentrating units 4104 of PMMA. The upper surface 4102 of each optical concentrating unit 4104 has a series of lenses 4106 (4106a, 4106b, 4106c, 4106d, 4106e, 4106f) arranged in concentric circles. In the center of the upper surface 4102 of each optical concentrating unit 4104 is a central circular flat portion 4170. Each lens 4106 has a convex lens surface 4146 (4146a, 4146b, 4146c, 4146d, 4146e, 4146f). The optical concentrating units 4104 are bonded to an upper structural layer 4124 (made of a sheet of glass) by bonding layer 4120 of EVA. Sandwiched between upper structural layer 4124 and lower structural layer 4126 (which is also a sheet of glass) are single-junction photovoltaic cells 4128, an electrical insulator 4130, an electrical conductor 4132 (illustrated for simplicity in FIG. 18 as a single layer), multiple-junction photovoltaic cells 4134, and encapsulation 4136. (Each of these components is otherwise similar to their counterparts in solar panel assembly 100 and, except as follows, will not be described in further detail herein.) In this embodiment, the lower surface 4272 of the upper structural layer 4124 has a hemispherical recess 4262 therein. The exposed “dome” of the recess is coated with a layer of aluminum metal 4264 forming a highly reflective mirrored surface. Between the aluminum metal layer 4264 and the glass of the upper structural layer 4124 and the conductor 4132 is a layer of aluminum oxide 4266, which acts as an insulator. The insulator 4130 and the conductor 4132 have an opening 4274 therein that is slightly larger than the hemispherical recess 4262 to allow light to enter the recess as is described below.

Optical redirecting/collecting units 4114 of PMMA are bonded to the lower structural surface 4126 by a bonding layer 4122 of EVA. Optical redirecting/collecting unites 4114 each comprise an optical redirecting unit 4116 and an optical collecting unit 4118. Extending upwards from the lower surface 4178 of each of the optical redirecting units 4116 into the body 4184 are a series of recesses 4140, which are filed with air. Each recess 4140 has a curved edge surface 4142 (having the shape of a portion of a paraboloid) and an edge surface 4186 opposite the edge surface 4142 having the shape of a portion of a right circular cylinder. Below the optical redirecting unit 4116 is an optical collecting unit 4118 (also of PMMA) that has an upper surface 4188 sealing the lower surface 4178 of the corresponding optical redirecting unit 4116, and a lower surface 4194 having a curved portion 4198 (having the shape of a revolved section of a parabola). Each of the structures described herein have a similar structure, function, and methods of assembly and use as with respect to their counterparts in solar panel assembly 100 and will not be described in further detail herein.

In FIG. 18, the path of direct sunlight rays 4144 through solar panel assembly 4100 can be seen. In this respect, direct sunlight rays 4144a,b impinge on the surface 4146a of the lens 4106a and are focused (as light rays 4148a,b (respectively)) towards the focus 4150a of the lens 4106a, which is at the exit of the passages 4138a in the encapsulation 4136. Traversing the focus 4150a (as light rays 4152a,b (respectively)), light rays 4152a,b continue to travel through the solar panel assembly 4100 and impinge upon the paraboloidal edge surface 4142a of recess 4140a. Light rays 4152a,b reflect off the paraboloidal edge surface 4142a because of total internal reflection and are reflected as light rays 4154a,b parallel to the axis (not shown) of the paraboloid defining the paraboloidal edge surface 4142a. (The focus of the paraboloid defining the paraboloidal edge surface 4142a is, in this embodiment, coincident with the focus 4150a of the lens 4106a.) Light rays 4154a,b continue to travel through the solar panel assembly 4100 and impinge upon the revolved parabolic curved portion 4198 of the lower surface 4194 of the optical collecting unit 4118. Light rays 4154a,b reflect off the revolved parabolic curved portion 4198 because of total internal reflection and are reflected as light rays 4156a,b (respectively) towards the focal point 4268a of the parabola defining the revolved paraboloic curved portion 4198. Light rays 4156a,b continue to travel past the focus 4268a (and diverge) and impinge on the aluminum metal layer 4264. The aluminum metal layer 4264 acts as a reflector and light rays 4256a,b reflect thereof towards the upper surface 4270 of the multiple-junction photovoltaic cells 4134 for harvesting thereby.

Similarly, direct sunlight rays 4144d,e impinge on the surfaces 4146d,e of the lenses 4106d,e (respectively) and are focused (as light rays 4148d,e (respectively)) towards the focuses 4150d,e of the lenses 4106d,e (respectively), which are at the exit of the passages 4138d,e (respectively) in the encapsulation 4136. Traversing the focuses 4150d,e (as light rays 4152d,e (respectively)), light rays 4152d,e continue to travel through the solar panel assembly 4100 and impinge upon the paraboloidal edge surface 4142d,e of recesses 4140d,e (respectively). Light rays 4152d,e (respectively) reflect off the paraboloidal edge surfaces 4142d,e (respectively) because of total internal reflection and are reflected as light rays 4154d,e (respectively) parallel to the axes (not shown) of the paraboloids defining the paraboloidal edge surfaces 4142d,e (respectively). (The focuses of the paraboloids defining the paraboloidal edge surfaces 4142d,e are, in this embodiment, coincident with the focuses 4150d,e of the lenses 4106d,e (respectively).) Light rays 4154d,e continue to travel through the solar panel assembly 4100 and impinge upon the revolved parabolic curved portion 4198 of the lower surface 4194 of the optical collecting unit 4118. Light rays 4154d,e reflect off the revolved parabolic curved portion 4198 because of total internal reflection and are reflected as light rays 4156d,e (respectively) towards the focal point 4268b of the parabola defining the revolved paraboloic curved portion 4198. Light rays 4156d,e continue to travel past the focus 4268b (and diverge) and impinge on the aluminum metal layer 4264. The aluminum metal layer 4264 acts as a reflector and light rays 4256d,e reflect thereof towards the upper surface 4270 of the multiple-junction photovoltaic cells 4134 for harvesting thereby.

In this embodiment, direct light rays (not shown) impinging upon the central flat portion 4170 of the upper surface 4102 of the optical concentrating unit 4104 of the solar panel assembly 4100 impinge upon the single-junction photovoltaic cell 4128.

No diffuse light rays have been shown imping upon the solar panel assembly 4100 in FIG. 18 in order to facilitate understanding. As was described above with respect to the first embodiment, in this embodiment, such light diffuse light rays would generally ultimately impinge about the single-junction photovoltaic cell 4128 for harvesting.

### Additional Disclosure

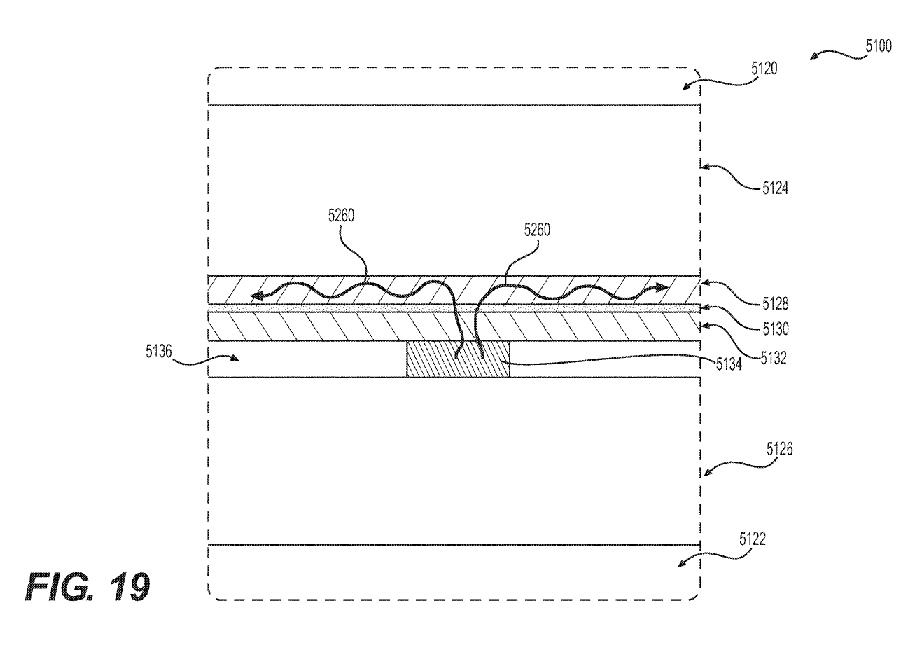

FIG. 19 is a close-up cross sectional schematic view of solar panel assembly 5100 illustrating heat dissipation in some embodiments of the present technology. Specifically boding layers 5120, 5122; structural layers 5124, 5126; single-junction photovoltaic cell 5128; electrical insulator 5130; electrical conductor 5132; multiple-junction photovoltaic cell 5134; and encapsulation 5136 (which may be similar to those described hereinabove) are shown in FIG. 19. In embodiments of the present technology that function as illustrated in this schematic, the majority of the thermal energy 5260 generated by the operation of the multiple-junction photovoltaic cell 5134 is dissipated by the single-junction photovoltaic cell 5128. This may occur in embodiments where the single junction photovoltaic cell 5128 is more thermally conductive than is the electrical insulator 5130 and the electrical conductor 5132. Such may be the case in one of the embodiments described hereinabove where the thermal conductivity, geometry, and sizing of the various components (e.g. structural layers 5124, 5126; single-junction photovoltaic cell 5128; electrical insulator 5130; electrical conductor 5132; and encapsulant 5136) is such that this occurs. Such may also (or in addition) be the case owing to a change in the materials of the various components. In a non-limiting example, where the electrical insulator 5130 is made of aluminum nitride (AlN)—which is a good electrical insulator and a good thermal conductor and the electrical conductor 5132 is a made of Titanium—which is a good electrical conductor but a poor thermal conductor—this may occur.

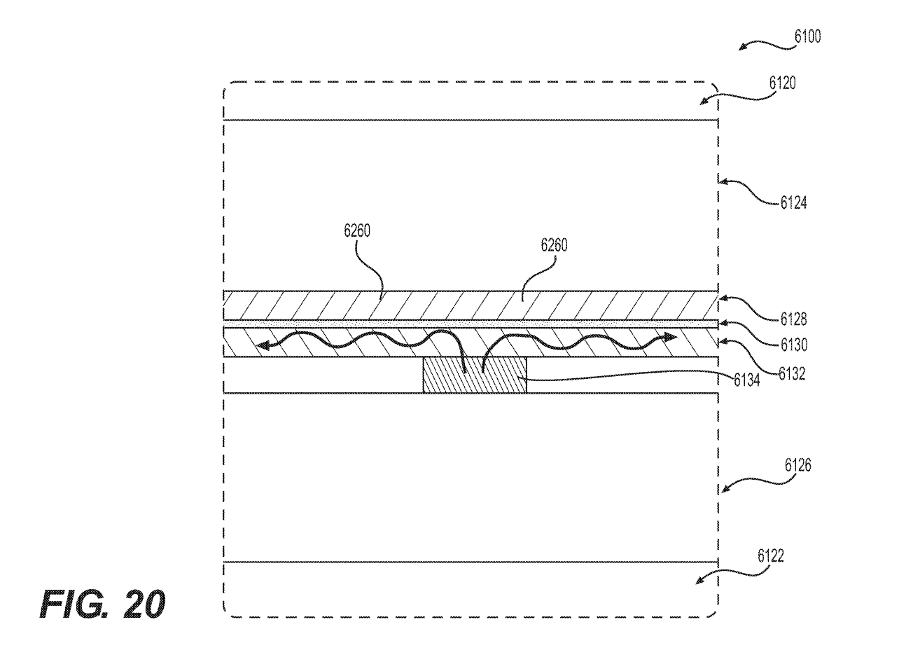

FIG. 20 is a close-up cross sectional schematic view of solar panel assembly 6100 illustrating heat dissipation in some embodiments of the present technology. Specifically boding layers 6120, 6122; structural layers 6124, 6126; single-junction photovoltaic cell 6128; electrical insulator 6130; electrical conductor 6132; multiple-junction photovoltaic cell 6134; and encapsulation 6136 (which may be similar to those described hereinabove) are shown in FIG. 20. In embodiments of the present technology that function as illustrated in this schematic, the majority of the thermal energy 6260 generated by the operation of the multiple-junction photovoltaic cell 6134 is dissipated by the electrical conductor 6132. This may occur in embodiments where the electrical conductor 6132 is more thermally conductive than is the electrical insulator 6130 and the single-junction photovoltaic cell 6128. Such may be the case in one of the embodiments described hereinabove where the thermal conductivity, geometry, and sizing of the various components (e.g. structural layers 6124, 6126; single-junction photovoltaic cell 6128; electrical insulator 6130; electrical conductor 6132; and encapsulation 6136) is such that this occurs. Such may also (or in addition) be the case owing to a change in the materials of the various components. In a non-limiting example, where the electrical conductor 6132 is made of copper metal (Cu)—which is a good electrical conductor and a good thermal conductor and the electrical insulator 6130 is a made of biaxially-oriented polyethylene terephthalate (BoPET—“Mylar”™)—which is both a good electrical and thermal insulator.

FIG. 21 is a close-up to plan schematic view of the lenses 7106 a solar panel assembly 7100 of the present technology illustrating the lenses 7106 being in a Cartesian array.

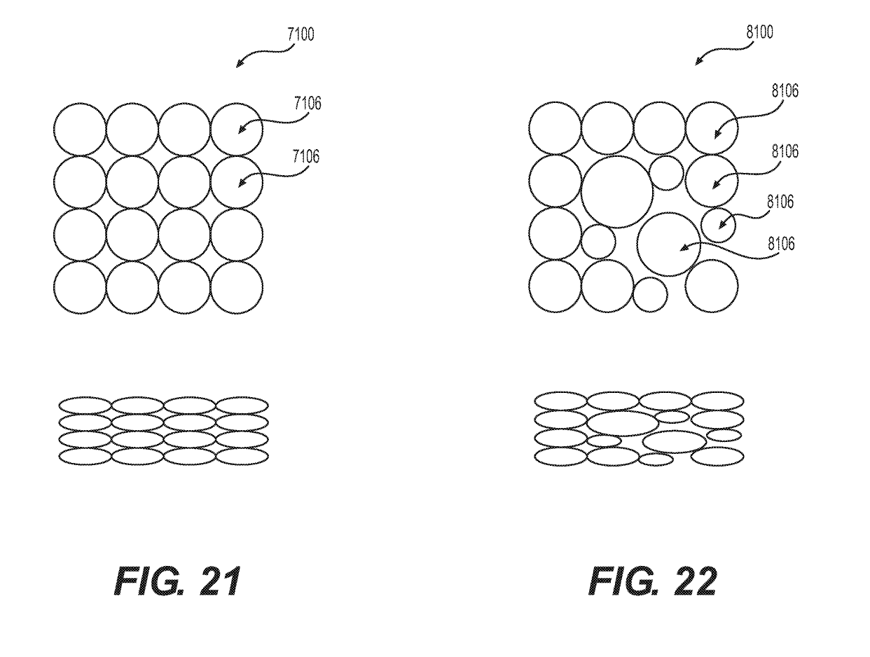

FIG. 22 is a close-up to plan schematic view of the lenses 8106 a solar panel assembly 8100 of the present technology illustrating the lenses 8106 being in a non-regularly-spaced algorithmically-determined array.

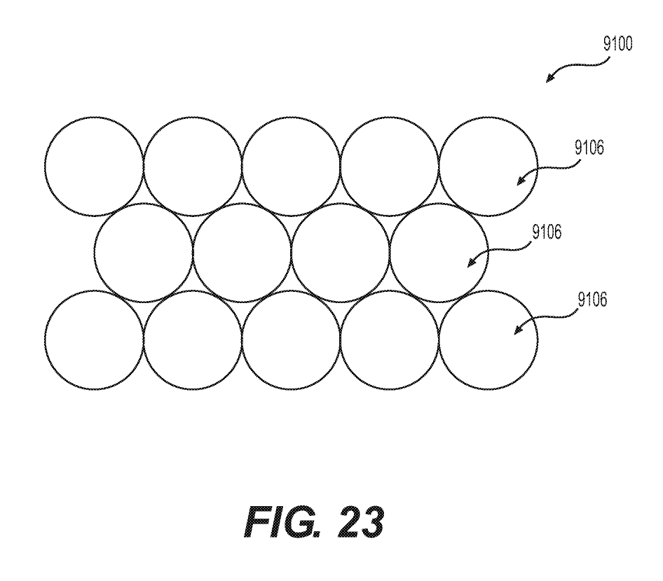

FIG. 23 is a close-up to plan schematic view of the lenses 9106 a solar panel assembly 9100 of the present technology illustrating the lenses 9106 being in a hexagonal array.

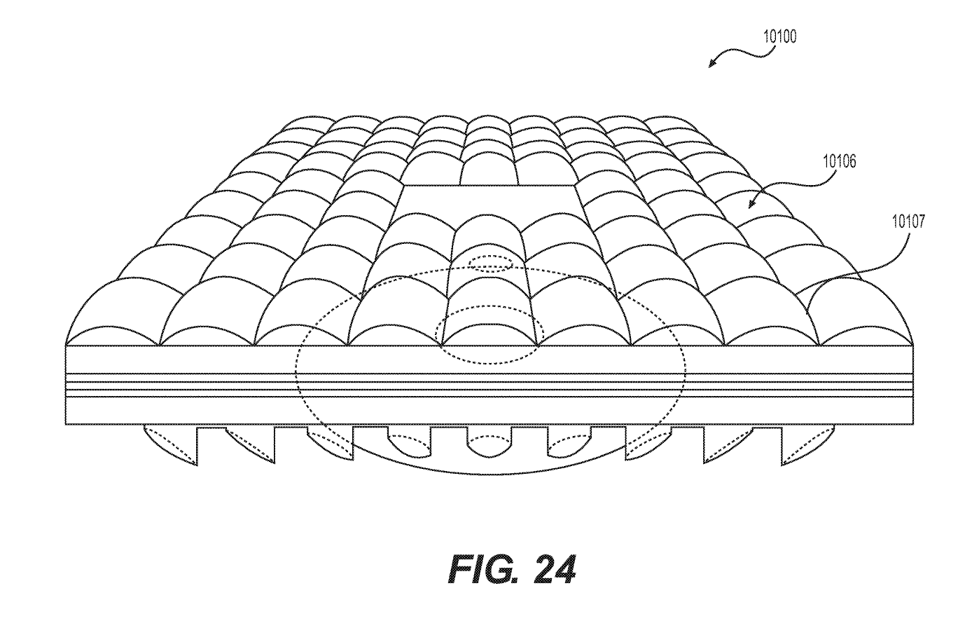

FIG. 24 is a perspective schematic view of a solar panel assembly 10100 of the present technology illustrating the lenses 10106 being in a closely-packed Cartesian array.

The lenses 10106 are square-shaped in plan view and there is little or no space 10107 between them (depending on the embodiment).

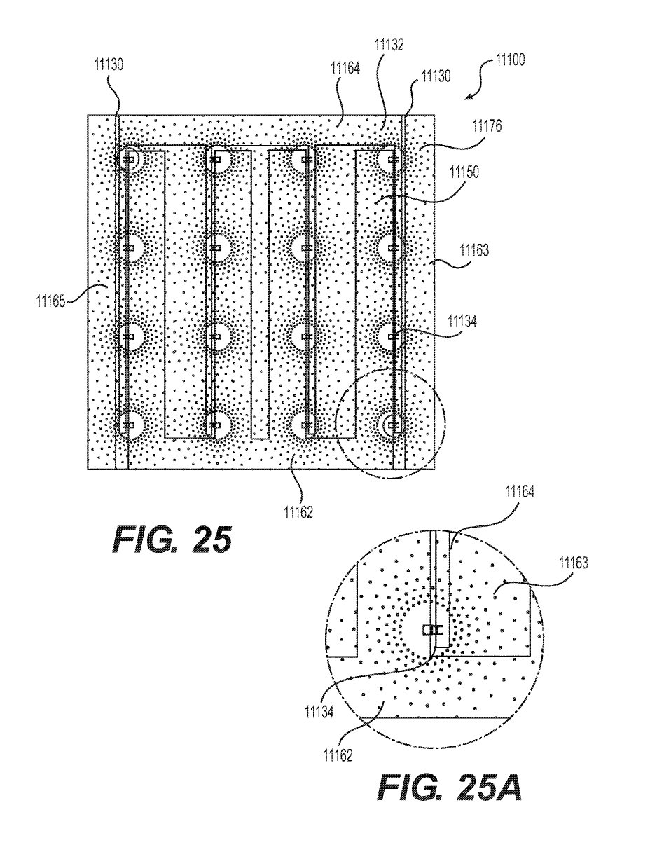

FIGS. 25 and 25A show a plan view of an electrical conductor 11132 and portions of an electrical insulator 11130 suitable for use in some embodiments of the present technology. As can be seen in FIG. 25, the electrical conductor 11132 is shaped to form two different current paths 11162, 11164 of an electrical circuit (unlabeled) that includes the multiple-junction photovoltaic cells 11134 associated with the a single-junction photovoltaic cell (not shown). The electrical circuit has “positive” current path 11162 connected to the positive terminal (unlabelled) of each of the multiple junction photovoltaic cells 11134 and a “negative” current path connected to the negative terminals 11166 of each of the multiple-junction photovoltaic cells 11134 (see also FIG. 25A showing a close-up view of these connections). Also shown in FIG. 25 are the terminals 11163, 11165 of the conductor for the single junction photovoltaic cell (not shown). In this construction, the electrical circuit formed for the single-junction photovoltaic cell is isolated from (in addition to being electrically separate from) that formed for the multiple junction photovoltaic cells 11134. The electrical conductor 11132 has a series of openings 11176 therein.

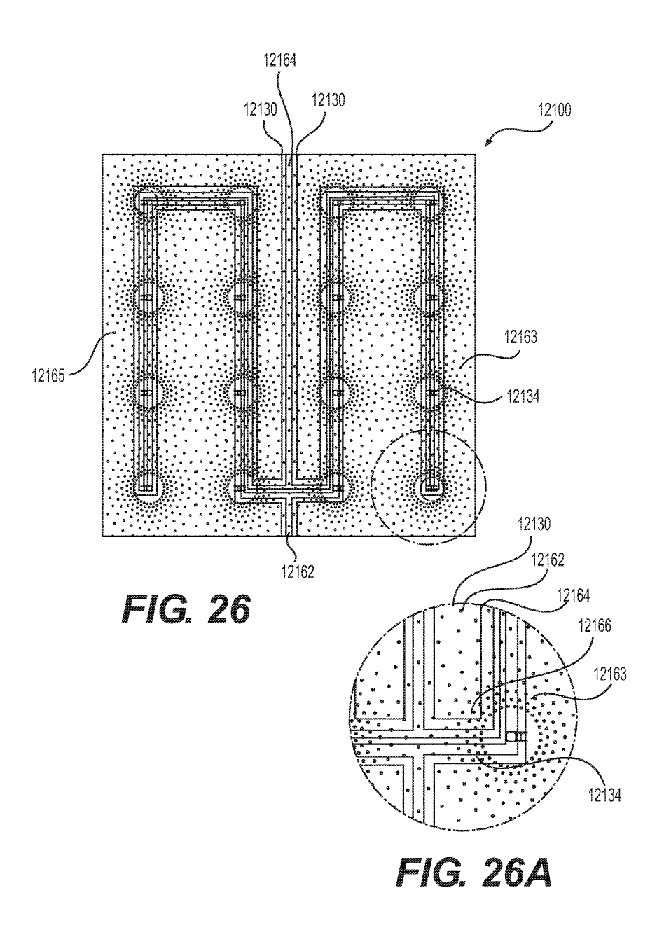

FIGS. 26 and 26A show a plan view of an electrical conductor 12132 and portions of an electrical insulator 12130 suitable for use in some embodiments of the present technology. As can be seen in FIG. 26, the electrical conductor 12132 is shaped to form two different current paths 12162, 12164 of an electrical circuit (unlabeled) that includes the multiple-junction photovoltaic cells 12134 associated with the a single-junction photovoltaic cell (not shown). The electrical circuit has “positive” current path 12162 connected to the positive terminal (unlabelled) of each of the multiple junction photovoltaic cells 12134 and a “negative” current path connected to the negative terminals 12166 of each of the multiple-junction photovoltaic cells 12134 (see also FIG. 26A showing a close-up view of these connections). Also shown in FIG. 26 are the terminals 12163, 12165 of the conductor for the single junction photovoltaic cell (not shown). In this construction, the electrical circuit formed for the single junction photovoltaic cell is intertwined with (although electrically separate from) that formed for the multiple-junction photovoltaic cells 12134. The electrical conductor 12132 has a series of openings 12176 therein.

Modifications and improvements to the above-described embodiments of the present technology may become apparent to those skilled in the art. The foregoing description is intended to be exemplary rather than limiting. The scope of the present technology is therefore intended to be limited solely by the scope of the appended claims.

1. A device for harvesting direct light and diffuse light from a light source, the device comprising:
a first photovoltaic cell, the first photovoltaic cell having an upper surface, a lower surface, and an array of optical passages therein in optical communication with the upper surface and the lower surface;
an array of optical concentrating elements above the upper surface of the first photovoltaic cell defining a light acceptance area, each of the optical concentrating elements being associated with one of the optical passages, each of the optical concentrating elements being structured and arranged to concentrate direct light from the light source impinging on that optical concentrating element towards the one of the optical passages associated with that optical concentrating element, the concentrated direct light passing through the first photovoltaic cell via the optical passage and exiting the first photovoltaic cell via the lower surface as a non-parallel beam of light, diffuse light from the light source passing through the array of optical concentrating elements to the upper surface of the first photovoltaic cell and entering the first photovoltaic cell for harvesting thereby; and
an array of optical redirecting elements below the lower surface of the first photovoltaic cell, each of the redirecting elements being associated with one of the optical passages, each of the redirecting elements receiving the beam of light from the optical passage with which that redirecting element is associated and redirecting the beam of light optically towards a second photovoltaic cell for harvesting thereby, the second photovoltaic cell having an active area receiving the beams of the light, the active area of the second photovoltaic cell being smaller than the light acceptance area defined by the array of optical concentrating elements by a concentration factor.

2. The device of claim 1, wherein the second photovoltaic cell has an upper surface and a lower surface, and the beams of light from the array of optical redirecting elements enter the second photovoltaic cell through the lower surface thereof.

3. (canceled)

4. The device of claim 2, wherein the upper surface of the second photovoltaic cell is adjacent the lower surface of the first photovoltaic cell.

5. The device of claim 1, wherein the second photovoltaic cell is vertically spaced apart from the first photovoltaic cell and has an upper surface and a lower surface, the beams of light from the array of optical redirecting elements entering the second photovoltaic cell through the upper surface thereof.

6. (canceled)

7. The device of claim 1, further comprising an optical collecting element, the optical collecting element receiving the beams of the light from the array of optical redirecting elements and reorienting the beams optically towards the second photovoltaic cell.

8. The device of claim 7, wherein, the optical collecting element reorients the beams of light directly towards the second photovoltaic cell.

9. The device of claim 1, wherein the redirecting elements redirect the beams of light directly towards the second photovoltaic cell.

10. The device of claim 1, wherein the optical concentrating elements are lenses.

11. The device of claim 10, wherein the lenses are arranged in a first pattern including a first series of concentric circles having a first common center, and for a one of the first series of concentric circles the lenses of that one of the first series of concentric circles are of a same surface area, the surface of the lenses increasing progressing away from the first common center.

12. The device of claim 10, wherein the lenses are arranged in a hexagonal array.

13. (canceled)

14. The device of claim 10, wherein the lenses are arranged in a non-regularly-spaced array.

15. The device of claim 1, wherein the optical passages are openings through the first photovoltaic cell.

16. (canceled)

17. The device of claim 1, wherein the optical redirecting elements are reflectors and redirecting the beam of light occurs via total internal reflection.

18-21. (canceled)

22. The device of claim 11, wherein the optical redirecting elements are arranged in a second pattern including a second series of concentric circles having a second common center.

23-29. (canceled)

30. The device of claim 10, wherein the lenses are formed in a first single layer of material

31. The device of claim 17, wherein the reflectors are formed in a second single layer of material.

32. The device of claim 25, wherein the revolved reflective surface is formed in a third single layer of material.

33. The device of claim 1, wherein the second photovoltaic cell is in thermal communication with the first photovoltaic cell, and the first photovoltaic cell is the primary heat sink of the second photovoltaic cell.

34. The device of claim 1, wherein the second photovoltaic cell is in thermal communication and electrical communication with an electric circuit sandwiched within the device, the electric circuit being the primary heat sink of the second photovoltaic cell, the electric circuit being electrically separated from the first photovoltaic cell by an electrical insulator.

35. The device of claim 1, wherein environmental albedo light enters the lower surface of the first photovoltaic cell for harvesting thereby.
